(19) United States
(12) Patent Application Publication
(10) Pub. No.: US 2011/0291702 A1
(43) Pub. Date: Dec. 1, 2011

(54) SIGNAL TRANSMISSION SYSTEM AND SIGNAL TRANSMISSION METHOD

(76) Inventor: Shunichi Kaeriyama, Tokyo (JP)

(21) Appl. No.: 13/147,663

(22) PCT Filed: Jan. 27, 2010
(86) PCT No.: PCT/JP2010/000464

§ 371 Date: Aug. 3, 2011

(30) Foreign Application Priority Data
Feb. 9, 2009 (JP) 2009-027723

(51) Int. Cl. H03K 19/0175

(52) U.S. Cl. 326/62

(57) ABSTRACT

A signal transmission system according to the present invention includes a first data conversion circuit (10) that converts first parallel data into first serial data (Ds) according to a first clock signal (CLKi); a clock multiplexing circuit (11) that outputs to a transmitting node a transmission signal (Dsm) obtained by multiplexing the first clock signal (CLKi) with the first serial data (Ds); a clock data recovery circuit (14) that extracts second serial data (Ds) corresponding to the first serial data and a second clock signal (CLKs) corresponding to the first clock signal (CLKi) from a reception signal (Drm) received through a receiving node; and a second data conversion circuit (15) that converts the second serial data (Ds) into second parallel data according to the second clock signal (CLKs). As a result, the chip area can be reduced.

### TECHNICAL FIELD

The present invention relates to a signal transmission system and a signal transmission method, and more particularly, to a signal transmission system and a signal transmission method for transmitting a signal through an AC coupling element.

### BACKGROUND ART

When signals are transmitted among a plurality of semiconductor chips having different power supply voltages, direct transmission of signals through lines causes a difference in DC voltage, which may result in damage to the semiconductor chips and failure of signal transmission. Accordingly, when signals are transmitted among a plurality of semiconductor chips having different power supply voltages, the semiconductor chips are connected with an AC coupling element to transmit only AC signals. Examples of the AC coupling element include a capacitor and a transformer. Here, the transformer refers to an AC coupling element including a primary coil and a secondary coil which are magnetically coupled together. When the transformer is used as the AC coupling element, a turn ratio between the primary coil and the secondary coil of the transformer is adjusted. This allows transfer of signals with an appropriate voltage amplitude to the semiconductor chip on the reception side, regardless of the voltage amplitude of a transmission signal from the semiconductor chip on the transmission side. Thus, the use of the transformer in communication between the semiconductor chips, which operate at different power supply voltages, eliminates the need to adjust the voltage amplitude of the transmission signal or reception signal on the semiconductor chips. Hereinafter, the transformer formed on a semiconductor chip is referred to as an on-chip transformer, as needed.

Examples of a signal transmission technique using transformers are disclosed in Patent Literatures 1 to 8. In the signal transmission methods disclosed in Patent Literatures 1 to 5, two transformers are used for signal transmission. When a data value transits from a first value to a second value, a pulse signal is sent to a first transformer, and when the data value transits from the second value to the first value, a pulse signal is sent to a second transformer.

In the signal transmission methods disclosed in Patent Literatures 1, 2, and 4 to 6, consecutive pulse signals are sent to transformers during a period in which data has the first value, and the signal levels of the signals to be sent to the transformers are fixed during a period in which the data has the second value.

In the signal transmission methods disclosed in Patent Literatures 1, 2, 4, and 5, consecutive pulse signals each having a first frequency are sent to transformers during the period in which the data has the first value, and consecutive pulse signals each having a second frequency are continuously sent to the transformers during the period in which the data has the second value. Further, in the signal transmission methods disclosed in Patent Literatures 1, 2, 4, and 5, two transformers are used. During the period in which the data has the first value, the same signal is sent to the two transformers, and during the period in which the data has the second value, signals having inverted phases are sent to the respective transformers.

In the signal transmission method disclosed in Patent Literature 7, when the data value transits from the first value to the second value, a signal having one pulse is sent to each transformer, and when the data value transits from the second value to the first value, a signal having two consecutive pulses is sent to each transformer.

In the signal transmission method disclosed in Patent Literature 8, when the data value transits from the first value to the second value, a pulse signal having a first amplitude is sent to each transformer, and when the data value transits from the second value to the first value, a pulse signal having a second amplitude is sent to each transformer.

In the signal transmission methods disclosed in Patent Literature 1 to 8, a pair of transformers is required to transmit and receive a single data signal. Accordingly, in order to transmit N (N is an integer) data signals through an insulating interface using the transformers of the related art, N number of transformers are required. Further, in order to transmit and receive differential signals, 2N number of transformers are required. When the transformers and the like are formed on semiconductor substrates, the transformers occupy a large area. The transfer of signals to be transmitted and received through a plurality of data signal lines via the transformers causes a problem of an increase in the area of the semiconductor chip.

In view of this, there have been proposed a number of serial communication methods for communicating information over a plurality of data signal lines through a single communication channel. Known examples of serial communication standards include PCI Express, USB (Universal Serial Bus), and SONET/SDH. In the serial communication, a clock signal synchronized with delimiters of serial signal data is used to convert a received serial signal into a parallel signal. Mainly two practical methods are used to generate this clock signal. The first method is a phase-locked loop (PLL) method. In the PLL method, the oscillation frequency and phase of a clock signal generated by an oscillator are synchronized with those of a serial signal. The second method is a delay-locked loop (DLL) method. In the DLL method, a delay of a clock signal is adjusted to synchronize a clock phase with a serial signal.

### CITATION LIST

### Patent Literature

[Patent Literature 1] U.S. Pat. No. 6,262,600
[Patent Literature 2] U.S. Pat. No. 6,525,566
[Patent Literature 3] U.S. Pat. No. 6,873,065
[Patent Literature 4] U.S. Pat. No. 6,903,578
[Patent Literature 5] U.S. Pat. No. 6,922,080
[Patent Literature 6] U.S. Pat. No. 7,302,247
[Patent Literature 7] U.S. Pat. No. 7,075,329

### [Patent Literature 8] Japanese Unexamined Patent Application Publication No. 08-236696

### SUMMARY OF INVENTION

### Technical Problem

As described above, even when the number of transformers is reduced by performing serial communication via the transformers, at least a transformer for data transmission/reception and a transformer for clock transmission are required. That is, the number of the transformers cannot be sufficiently reduced even by applying a serial communication technique to the signal transmission via the transformers.

Further, when a clock reproduction technique, which is used for the serial communication technique, is employed, circuits for reproducing clock signals using the PLL method and DLL method are required on the reception side. The PLL circuit and the DLL circuit have a large circuit area, which results in a problem of an increase in the area of a semiconductor chip. Both the PLL method and the DLL method require to externally provide an oscillator, such as a crystal oscillator, in order to obtain a reference clock signal. This causes a problem of an increase in the mounting area and an increase in the number of components.

Accordingly, when the transformers are arranged on a chip, a sufficient reduction in the chip area cannot be achieved even by a combination of the signal transmission method using transformers and the serial communication technique. Therefore, the present invention aims to reliably transfer signals to be transmitted and received through a plurality of data lines by using a circuit with a small number of transformers and a small circuit area.

### Solution to Problem

One aspect of the present invention is a signal transmission system including: an AC coupling element that is connected between a transmitting node and a receiving node and couples the transmitting node and the receiving node in an alternating manner, the transmitting node and the receiving node being provided on semiconductor substrates electrically insulated from each other; a first data conversion circuit that receives first parallel data and a first clock signal, and converts the first parallel data into first serial data according to the first clock signal; a clock multiplexing circuit that multiplexes the first clock signal with the first serial data to generate a transmission signal, and outputs the transmission signal to the transmitting node; a clock data recovery circuit that extracts second serial data corresponding to the first serial data and a second clock signal corresponding to the first clock signal from a reception signal received through the receiving node; and a second data conversion circuit that converts the second serial data into second parallel data according to the second clock signal.

Another aspect of the present invention is a signal transmission method for transmitting and receiving a signal through an AC coupling element that is connected between a transmitting node and a receiving node and couples the transmitting node and the receiving node in an alternating manner, the transmitting node and the receiving node being provided on semiconductor substrates electrically insulated from each other, the signal transmission method including: converting first parallel data to be transmitted into first serial data according to a clock signal; generating a transmission signal by multiplexing the clock signal with the first serial data; transmitting the transmission signal to the receiving node through the AC coupling element; extracting second serial data corresponding to the first serial data and a second clock signal corresponding to the first clock signal from a reception signal received through the receiving node; and converting the second serial data into second parallel data according to the second clock signal.

### Advantageous Effects of Invention

A signal transmission system and a signal transmission method of the present invention aim to reliably transfer signals to be transmitted and received through a plurality of data lines by using a circuit with a small number of transformers and a small circuit area.

### BRIEF DESCRIPTION OF DRAWINGS

FIG. 1 is a schematic view showing a mounted state of a signal transmission system according to a first exemplary embodiment;

FIG. 2 is a schematic view showing a mounted state of the signal transmission system according to the first exemplary embodiment;

FIG. 3 is a schematic view showing a mounted state of the signal transmission system according to the first exemplary embodiment;

FIG. 4 is a schematic view showing a mounted state of the signal transmission system according to the first exemplary embodiment;

FIG. 5 is a schematic view showing a mounted state of the signal transmission system according to the first exemplary embodiment;

FIG. 6 is a schematic view showing a mounted state of the signal transmission system according to the first exemplary embodiment;

FIG. 7 is a schematic view showing a mounted state of the signal transmission system according to the first exemplary embodiment;

FIG. 8 is a schematic view showing a mounted state of the signal transmission system according to the first exemplary embodiment;

FIG. 9 is a schematic view showing a sectional view of a semiconductor substrate when a mounting method shown in FIG. 8 is employed;

FIG. 10 is a schematic view showing a sectional view of the semiconductor substrate when the mounting method shown in FIG. 8 is employed;

FIG. 11 is a block diagram of the signal transmission system according to the first exemplary embodiment;

FIG. 12 is a circuit diagram of a clock multiplexing circuit according to the first exemplary embodiment;

FIG. 13 is a circuit diagram showing a pre-buffer of the clock multiplexing circuit according to the first exemplary embodiment;

FIG. 14 is a circuit diagram showing another example of the pre-buffer shown in FIG. 13;

FIG. 15 is a timing diagram showing operation of the clock multiplexing circuit according to the first exemplary embodiment;

FIG. 16 is a block diagram of a clock data recovery circuit according to the first exemplary embodiment;

FIG. 17 is a circuit diagram of a pulse detector (positive amplitude) of the clock recovery circuit according to the first exemplary embodiment;

FIG. 18 is a circuit diagram showing another example of the pulse detector shown in FIG. 17;

FIG. 19 is a circuit diagram of a pulse detector (negative amplitude) of the clock data recovery circuit according to the first exemplary embodiment;

FIG. 20 is a circuit diagram showing another example of the pulse detector shown in FIG. 19;

FIG. 21 is a circuit diagram of a hysteresis comparator of the clock data recovery circuit according to the first exemplary embodiment;

FIG. 22 is an operating characteristic diagram of the hysteresis comparator shown in FIG. 21;

FIG. 23 is a timing diagram showing operation of the clock data recovery circuit according to the first exemplary embodiment;

FIG. 24 is a timing diagram showing operation of the signal transmission system according to the first exemplary embodiment;

FIG. 25 is a timing diagram showing another example of output characteristics of the clock multiplexing circuit according to the first exemplary embodiment;

FIG. 26 is a timing diagram showing another example of output characteristics of the clock multiplexing circuit according to the first exemplary embodiment;

FIG. 27 is a schematic view showing a mounted state of a signal transmission system according a second exemplary embodiment;

FIG. 28 is a schematic view showing a mounted state of the signal transmission system according to the second exemplary embodiment;

FIG. 29 is a block diagram of the signal transmission system according to the second exemplary embodiment;

FIG. 30 is a timing diagram showing operation of the signal transmission system according to the second exemplary embodiment;

FIG. 31 is a schematic view showing a mounted state of a signal transmission system according to a third exemplary embodiment;

FIG. 32 is a schematic view showing a mounted state of the signal transmission system according to the third exemplary embodiment;

FIG. 33 is a block diagram of the signal transmission system according to the third exemplary embodiment;

FIG. 34 is a block diagram of a signal transmission system according to a fourth exemplary embodiment;

FIG. 35 is a block diagram of a waveform shaping circuit according to the fourth exemplary embodiment;

FIG. 36 is a timing diagram showing operation of the waveform shaping circuit shown in FIG. 35;

FIG. 37 is a block diagram of a signal transmission system according to a fifth exemplary embodiment;

FIG. 38 is a block diagram of a signal transmission system according to a sixth exemplary embodiment;

FIG. 39 is a timing diagram showing operation of the signal transmission system according to the sixth exemplary embodiment;

FIG. 40 is a block diagram showing a signal transmission system according to a seventh exemplary embodiment;

FIG. 41 is a block diagram of a signal transmission system according to an eighth exemplary embodiment; and

FIG. 42 is a block diagram of a signal transmission system according to a ninth exemplary embodiment.

### DESCRIPTION OF EMBODIMENTS

### First Exemplary Embodiment

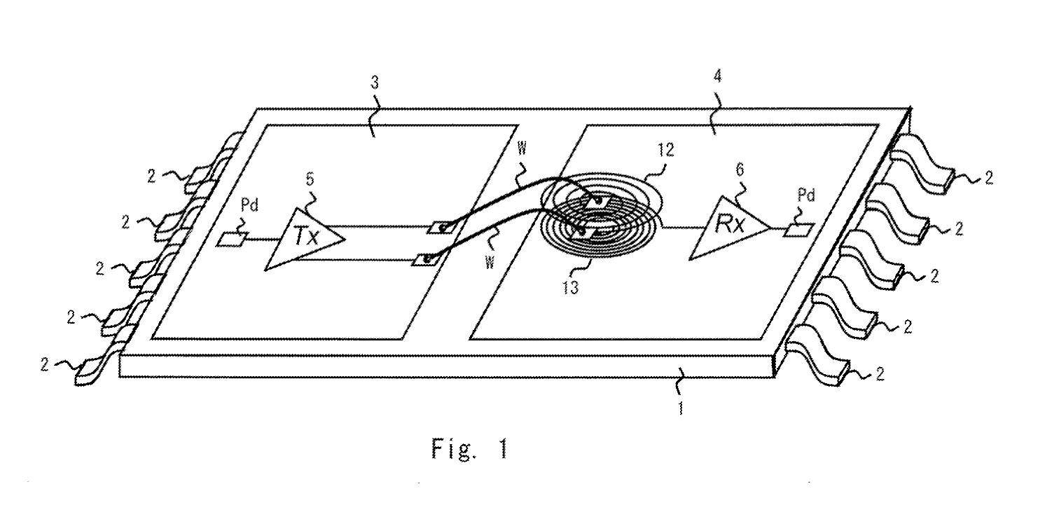

Hereinafter, exemplary embodiments of the present invention will be described with reference to the drawings. First, a method for mounting a signal transmission system according to this exemplary embodiment will be described. In the signal transmission system according to this exemplary embodiment, transformers are constituted using two coils formed on one or two semiconductor chips. In other words, the two coils function as AC coupling elements (for example, transformers) magnetically coupled together. A primary coil is connected to a transmitting node of a transmission circuit formed on the semiconductor chip, and a secondary coil is connected to a receiving node of a reception circuit. FIGS. 1 to 10 show schematic views each illustrating a mounted state of the signal transmission system according to this exemplary embodiment.

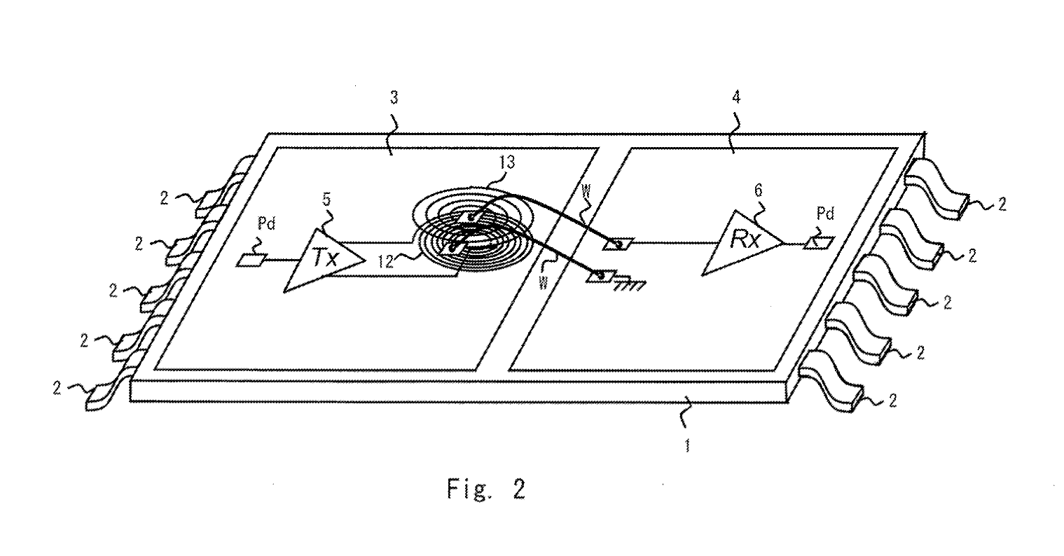

In the mounted state shown in FIG. 1, a first semiconductor chip 3 and a second semiconductor chip 4 are mounted in a semiconductor package 1. Each of the first semiconductor chip 3 and the second semiconductor chip 4 includes a pad Pd. The pads Pd of the first semiconductor chip 3 and the second semiconductor chip 4 are connected to lead terminals 2 which are provided in the semiconductor package 1 through bonding wires that are not shown. This configuration is common to the mounting modes shown in FIGS. 2 to 8.

A transmission circuit 5 is formed on the first semiconductor chip 3. Meanwhile, a primary coil 12, a secondary coil 13, and a reception circuit 6 are formed on the second semiconductor chip 4. A pad connected to the transmission circuit 5 is formed on the first semiconductor chip 3, and a pad connected to the primary coil 12 is formed on the second semiconductor chip 4. The transmission circuit 5 is connected to the primary coil 12, which is formed above the semiconductor chip 4, through the pad and a bonding wire W.

In the mounted state shown in FIG. 2, the primary coil 12, the secondary coil 13, and the transmission circuit 5 are formed on the first semiconductor chip 3. Meanwhile, the reception circuit 6 is formed on the second semiconductor chip 4. A pad connected to the secondary coil 13 is formed on the first semiconductor chip 3, and a pad connected to the reception circuit 6 is formed on the second semiconductor chip 4. The reception circuit 6 is connected to the secondary coil 13, which is formed above the first semiconductor chip 4, through the pad and the bonding wire W.

In the examples shown in FIGS. 1 and 2, the primary coil 12 and the secondary coil 13 are formed using a first wiring layer and a second wiring layer which are vertically stacked within one semiconductor chip.

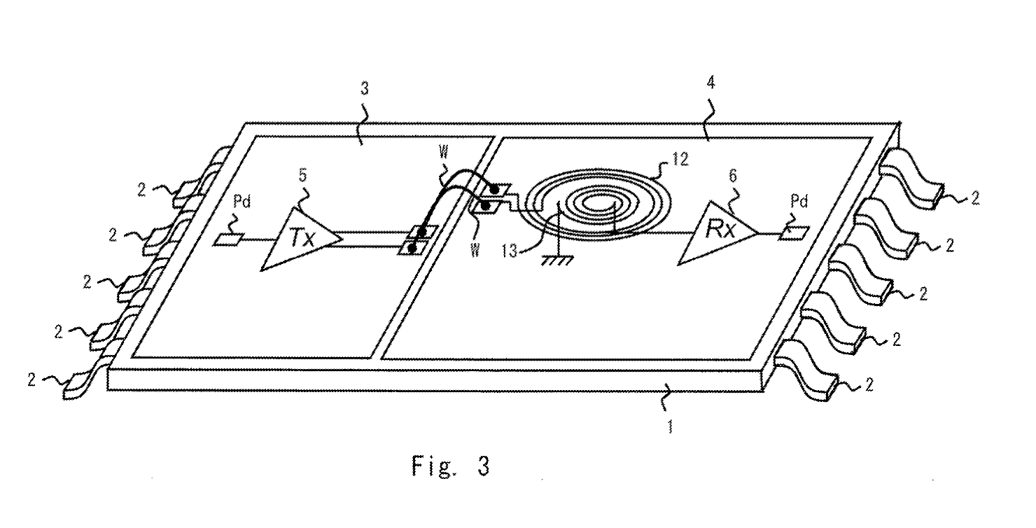

In the mounted state shown in FIG. 3, the transmission circuit 5 is formed on the first semiconductor chip 3. Meanwhile, the primary coil 12, the secondary coil 13, and the reception circuit 6 are formed on the second semiconductor chip 4. A pad connected to the transmission circuit 5 is formed on the first semiconductor chip 3, and, a pad connected to the primary coil 12 is formed on the second semiconductor chip 4. The transmission circuit 5 is connected to the primary coil 12, which is formed on the second semiconductor chip 4, through the pad and the bonding wire W.

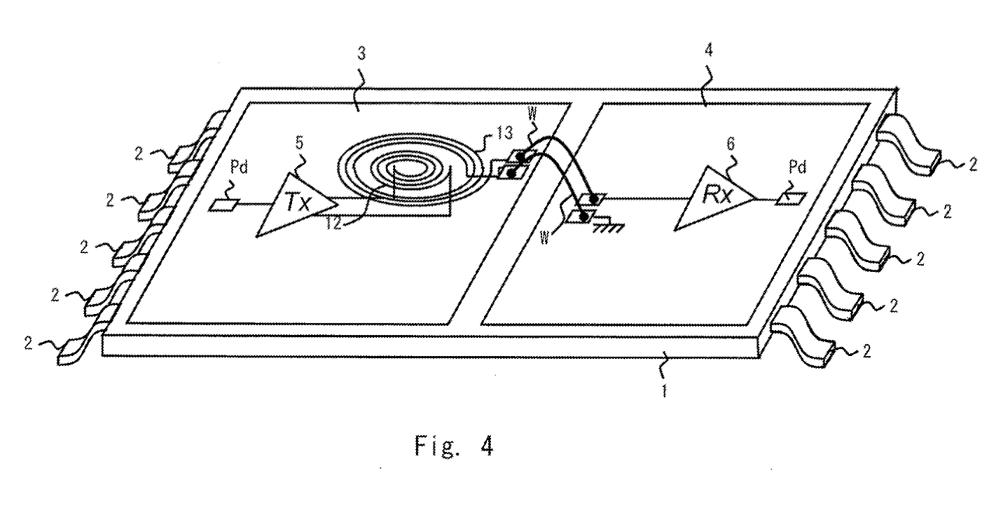

In the mounted state shown in FIG. 4, the primary coil 12, the secondary coil 13, and the transmission circuit 5 are formed on the first semiconductor chip 3. Meanwhile, the reception circuit 6 is formed on the second semiconductor chip 4. A pad connected to the secondary coil 13 is formed on the first semiconductor chip 3, and a pad connected to the reception circuit 6 is formed on the second semiconductor chip 4. The reception circuit 6 is connected to the secondary coil 13, which is formed above the first semiconductor chip 3, through the pad and the bonding wire W.

In the examples shown in FIGS. 3 and 4, the primary coil 12 and the secondary coil 13 are formed in the same wiring layer on one semiconductor chip. The primary coil 12 and the secondary coil 13 are formed as coils which have the same center position.

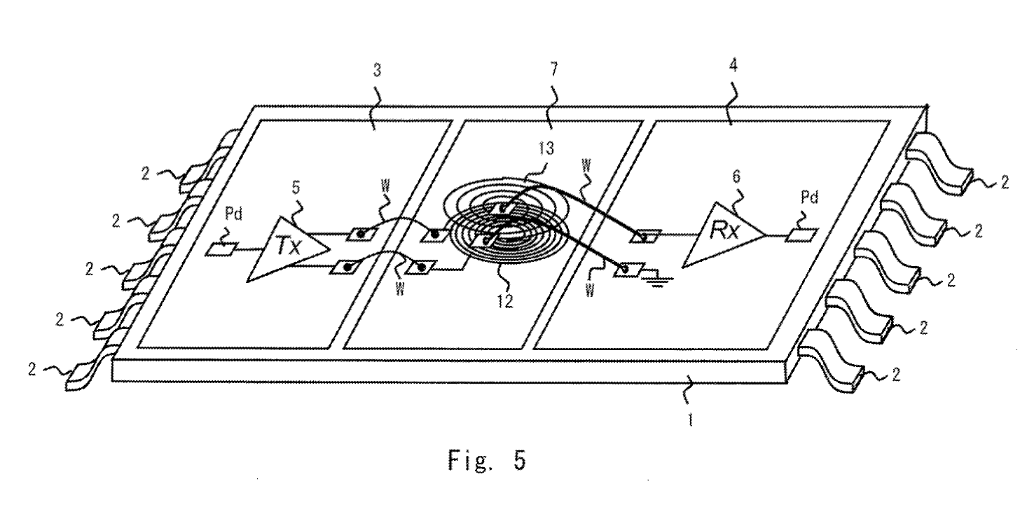

In the mounted state shown in FIG. 5, the transmission circuit 5 is formed on the first semiconductor chip 3, and the reception circuit 6 is formed on the second semiconductor chip 4. The primary coil 12 and the secondary coil 13 are formed on a third semiconductor chip 7. A pad connected to the primary coil 12 is formed on the first semiconductor chip 3, and a pad connected to the secondary coil 13 is formed on the second semiconductor chip 4. A pad connected to the primary coil 12 and a pad connected to the secondary coil 13 are formed above the third semiconductor chip 7. The transmission circuit 5 is connected to the primary coil 12, which is formed on the third semiconductor chip 7, through the pad and the bonding wire W, and the reception circuit 6 is connected to the secondary coil 13, which is formed above the third semiconductor chip 7, through the pad and the bonding wire W. Note that in the example shown in FIG. 5, the primary coil 12 and the secondary coil 13 are formed using the first wiring layer and the second wiring layer which are vertically stacked within one semiconductor chip.

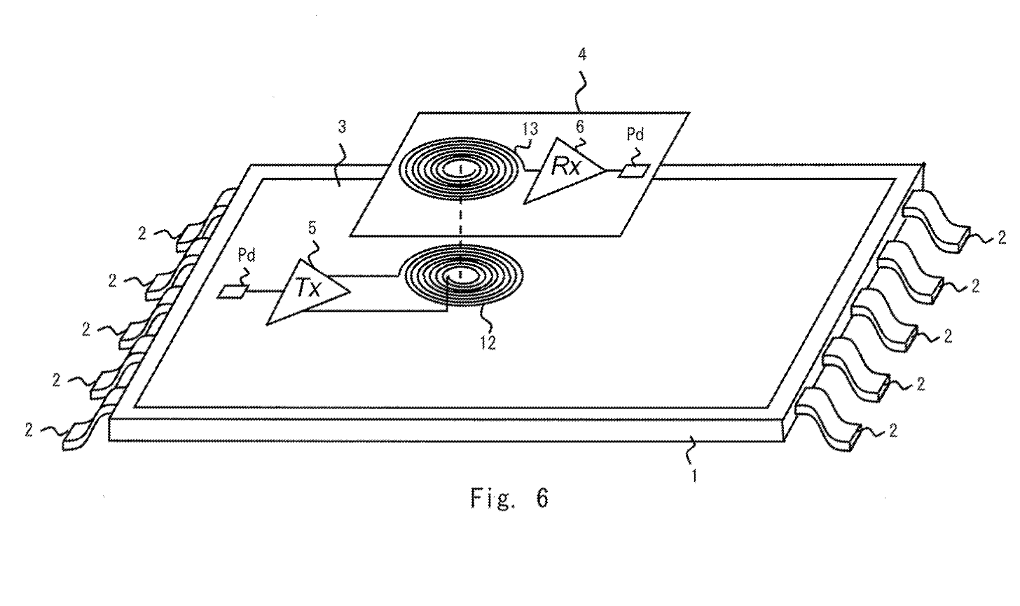

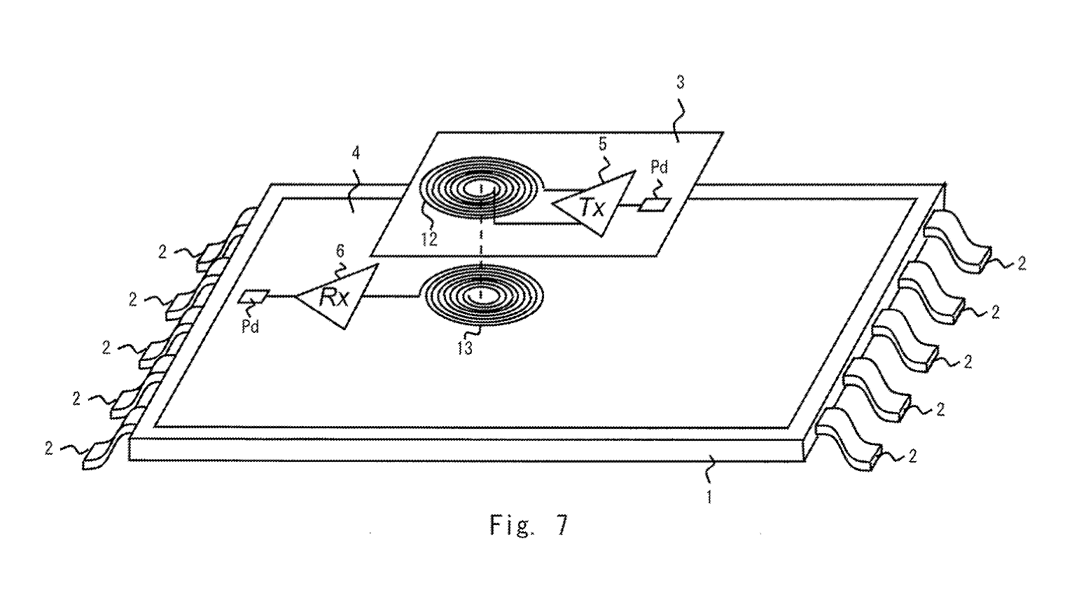

FIGS. 6 and 7 each show an example in which the transmission circuit 5 and the primary coil 12 are formed on a first semiconductor substrate and the reception circuit 6 and the secondary coil 13 are formed on a second semiconductor substrate. In the examples shown in FIGS. 6 and 7, the first semiconductor chip 3 and the second semiconductor chip 4 are stacked. Additionally, in the examples shown in FIGS. 6 and 7, the first semiconductor chip 3 and the second semiconductor chip 4 are arranged so that the center positions of the primary coil 12 and the secondary coil 13 are aligned in the stacked state.

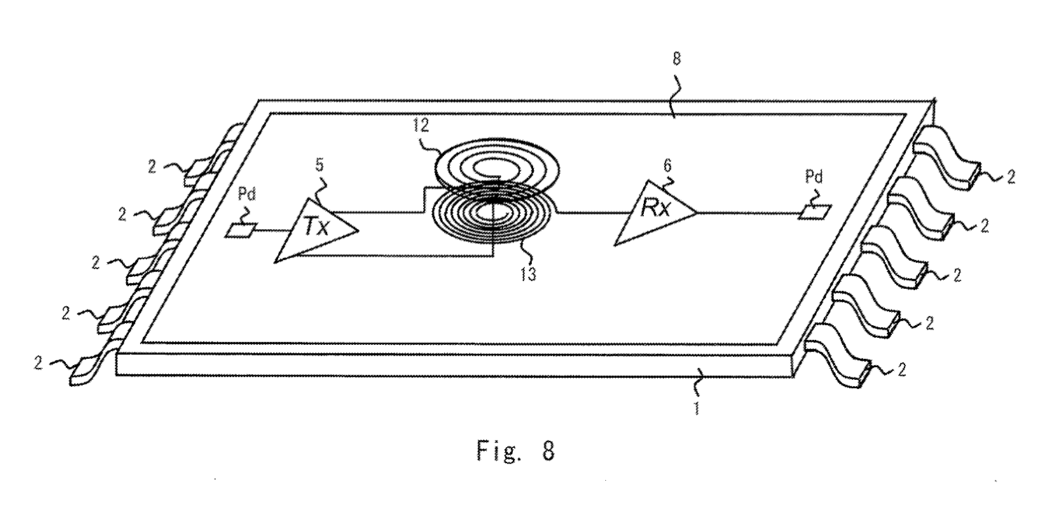

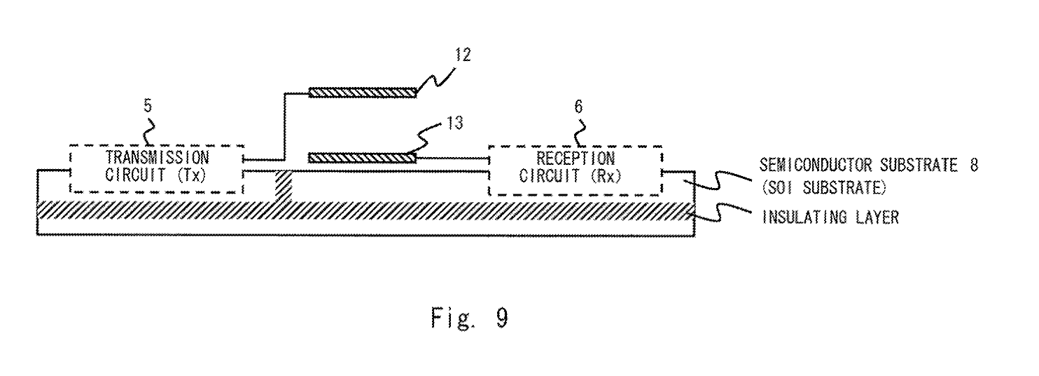

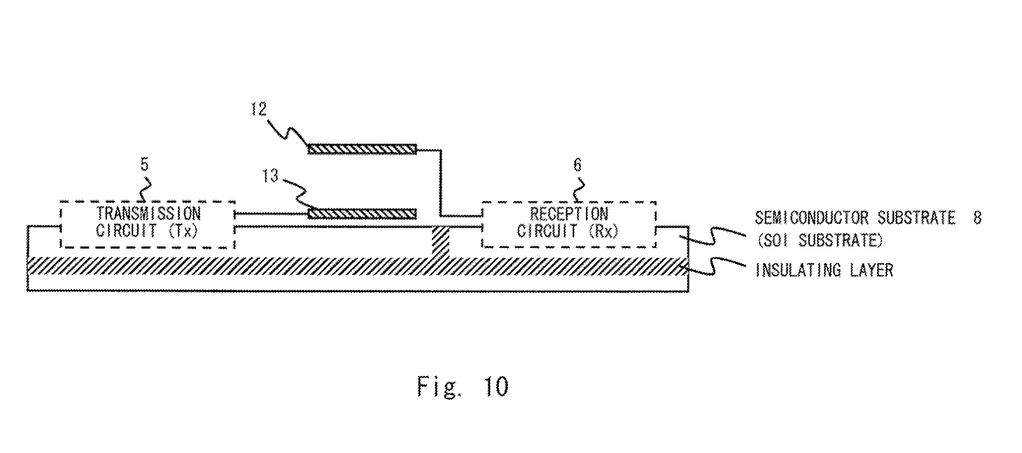

In the example shown in FIG. 8, the transmission circuit 5, the reception circuit 6, the primary coil 12, and the secondary coil 13 are formed on a semiconductor substrate 8. In the example shown in FIG. 8, the primary coil 12 and the secondary coil 13 are formed using the first wiring layer and the second wiring layer which are vertically stacked. A region where the transmission circuit 5 is disposed and a region where the reception circuit 6 is disposed are electrically insulated from each other by an insulating layer formed on the semiconductor substrate 8. FIGS. 9 and 10 each show a sectional view of the semiconductor substrate 8. In the example shown in FIG. 9, the region where the transmission circuit 5 and the region where the reception circuit 6 is formed are electrically separated by an insulating layer. The primary coil 12 and the secondary coil 13 are provided in the region where the reception circuit 6 is formed. Meanwhile, in the example shown in FIG. 10, the region where the transmission circuit 5 is formed and the region where the reception circuit 6 is formed are electrically separated by an insulating layer. The primary coil 12 and the secondary coil 13 are provided in the region where the transmission circuit 5 is formed.

As described above, in the signal transmission system according to this exemplary embodiment, the transformers for use in communication are formed on the semiconductor chips. At this time, the primary coil 12 and the secondary coil 13 may be arranged so that the center positions thereof are aligned, and there is no limitation on the region where the transformers are formed. Furthermore, in the signal transmission system according to this exemplary embodiment, transmission target data to be transmitted through a plurality of data lines using a single transformer and a clock synchronous with the transmission target data are transmitted and received by a single transformer. The signal transmission system according to this exemplary embodiment will be described in detail below. Though only the transmission circuit 5 and the reception circuit 6 are illustrated above as the circuits formed on the semiconductor chips, circuits other than the transmission circuit 5 and the reception circuit 6 may be formed on the semiconductor chips.

FIG. 11 shows a block diagram of the signal transmission system according to this exemplary embodiment. As shown in FIG. 11, the signal transmission system according to this exemplary embodiment includes at least the transmission circuit 5, the transformers, and the reception circuit 6. Here, the transformers are composed of the primary coil 12 and the secondary coil 13.

The transmission circuit 5 includes a plurality of input terminals, a first data conversion circuit (for example, a multiplexer 10), and a clock multiplexing circuit 11. The input terminals respectively correspond to data Din0 to Din3, which are included in first parallel data, and a first clock signal CLKi. The data Din0 to Din3 and the first clock signal CLKi may be input from another circuit provided in the first semiconductor chip 3, or may be supplied from another semiconductor device.

The multiplexer 10 receives the first parallel data and the first clock signal CLKi, and converts the first parallel data into first serial data Ds according to the first clock signal CLKi. This first serial data Ds is composed of a sequence of serially arranged data Dine) to Din3 included in the first parallel data in synchronization with the first clock signal CLKi. That is, the multiplexer 10 time-division multiplexes the received first parallel data and generates the first serial data Ds. The multiplexer 10 serves as a parallel-to-serial converter. For example, a selector or a shift register may be used as the multiplexer.

The clock multiplexing circuit 11 multiplexes the first clock signal CLKi with the first serial data Ds, and generates a transmission signal Dsm. Further, the clock multiplexing circuit 11 outputs the transmission signal Dsm to the primary coil 12 through the transmitting node. Both ends of the primary coil 12 are connected to the clock multiplexing circuit 11. This is because the clock multiplexing circuit 11 according to this exemplary embodiment drives the primary coil 12 by using a current in the positive direction and a current in the negative direction. In other words, the connection mode between the primary coil 12 and the clock multiplexing circuit 11 is changed depending on the drive system of the clock multiplexing circuit 11. This clock multiplexing circuit 11 will be described in detail later.

The reception circuit 6 includes a plurality of output terminals, a clock data recovery circuit 14, and a second data conversion circuit (for example, a demultiplexer 15). The input terminals respectively correspond to data Dout0 to Dout3, which are included in second parallel data, and the first clock signal CLKi. The data Dout0 to Dout3 and the first clock signal CLKi may be output to another circuit provided in the second semiconductor chip 4, or may be output to a circuit provided in another semiconductor device.

A clock signal for recognizing a delimiter of serial data is typically required in serial communication. In a source synchronous system, this clock signal is received through a channel different from a channel for data communication. Meanwhile, in this exemplary embodiment, the source synchronous system is not employed to prevent an increase in the number of channels. Instead, the clock data recovery circuit 14 is used in this exemplary embodiment. The clock data recovery circuit 14 extracts a clock signal from a reception signal Drm (for example, a NRZ (Non-Return to Zero) data signal) which is received through the secondary coil 13 and the receiving node. The clock data recovery circuit 14 according to this exemplary embodiment also extracts second serial data Dr from the reception signal Drm. This second serial data Dr corresponds to the first serial data Ds. The clock data recovery circuit 14 will be described in detail later.

The demultiplexer 15 converts the second serial data Dr into the second parallel data according to a second clock signal CLKs. This second parallel data is obtained by sampling the data Din0 to Din3 included in the second serial data Ds in synchronization with the second clock signal CLKs. That is, the demultiplexer 15 serves as a serial-to-parallel converter. For example, a selector or a shift register may be used as the demultiplexer.

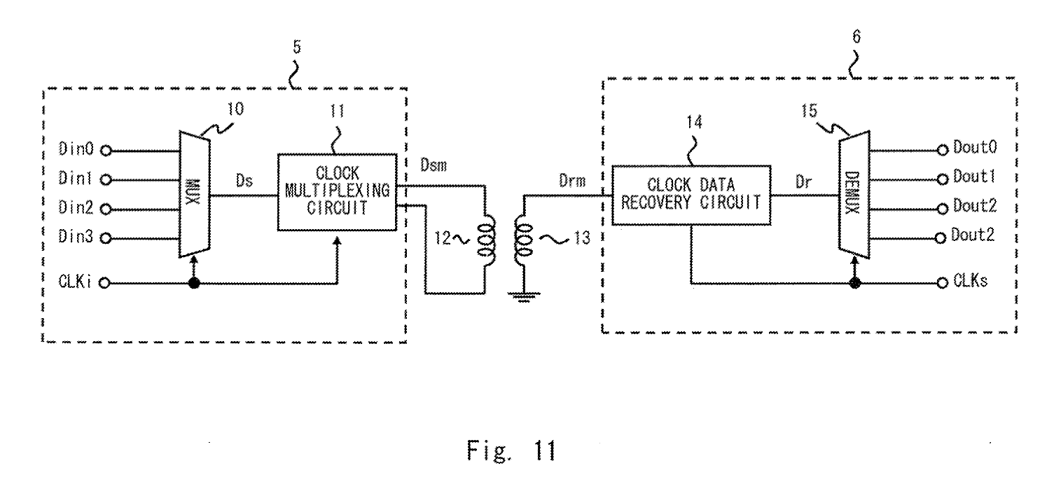

Subsequently, details of the clock multiplexing circuit 11 will be described. The clock multiplexing circuit 11 multiplexes the first clock signal CLKi with the first serial data Ds. The waveform based on the first clock signal CLKi multiplexed by the clock multiplexing circuit 11 may be arbitrarily determined depending on the specifications of the signal transmission system. For example, the waveform based on the clock signal may be a pulse signal or a sign wave, for example. The shape of a pulse signal may be determined so that the fluctuation direction, the amplitude, or the number of pulse signals changes depending on the logic level of the first serial data Ds. Hereinafter, a pulse signal is mainly used as a waveform to be multiplexed according to the clock signal. The fluctuation direction of the pulse signal changes depending on the logic level of the first serial data Ds. It is assumed hereinafter that the rising waveform and the falling waveform of the pulse signal are asymmetrical, but the rising waveform and the falling waveform may be symmetrical. FIG. 12 shows a circuit diagram of the clock multiplexing circuit 11. As shown in FIG. 12, the clock multiplexing circuit 11 includes an inverter 20, AND circuits 21 and 23, pre-buffers 22 and 24, PMOS transistors P1 and P2, and NMOS transistors N1 and N2.

The inverter 20 inverts the logic level of the first serial data Ds and outputs the resultant data. An output node of the inverter 20 is referred to as a node ND2. The AND circuit 21 receives the first clock signal CLKi and the first serial data Ds, and outputs a result of an AND operation between these signals. The AND circuit 23 receives the first clock signal CLKi and the first serial data Ds which is inverted by the inverter 20, and outputs a result of an AND operation between these signals. The pre-buffer 22 drives the NMOS transistor N1 based on the output of the AND circuit 21. An output node of the pre-buffer 22 is referred to as ND1. The pre-buffer 24 drives the NMOS transistor N2 based on the output of the AND circuit 23. An output node of the pre-buffer 24 is referred to as ND3.

The PMOS transistor P1 and the NMOS transistor N1 are connected in series between a power supply terminal and a ground terminal. A node connecting the drain of the PMOS transistor P1 and the drain of the NMOS transistor N1 is connected to one terminal of the primary coil 12 through the transmitting node. The gate of the PMOS transistor P1 receives the first serial data Ds. The gate of the NMOS transistor N1 receives the output of the pre-buffer 22.

The PMOS transistor P2 and the NMOS transistor N2 are connected in series between the power supply terminal and the ground terminal. A node connecting the drain of the PMOS transistor P2 and the drain of the NMOS transistor N2 is connected to the other terminal of the primary coil 12 through the transmitting node. The gate of the PMOS transistor P2 receives the first serial data Ds which is inverted by the inverter 20. The gate of the NMOS transistor N2 receives the output of the pre-buffer 24.

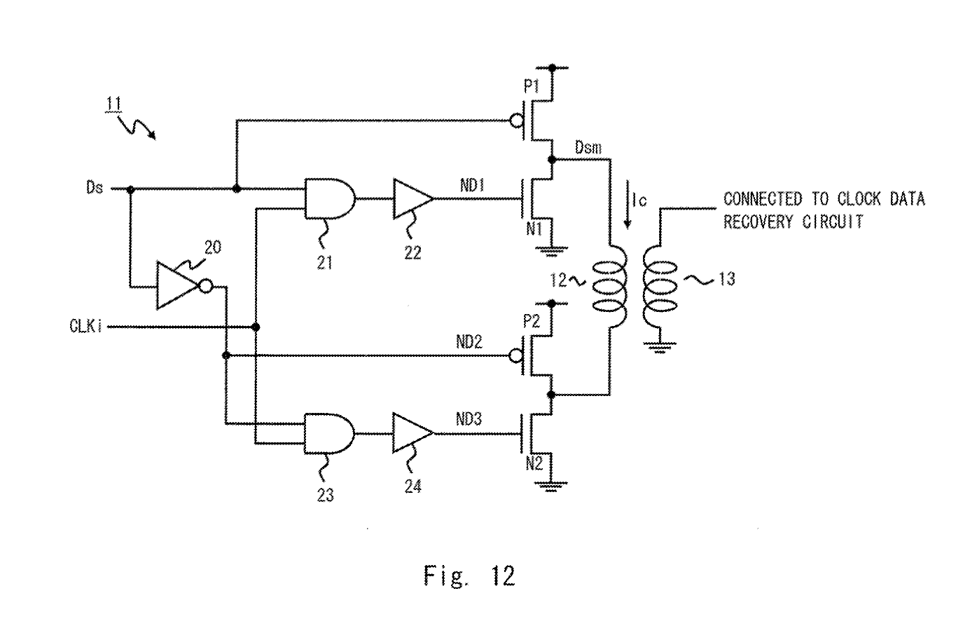

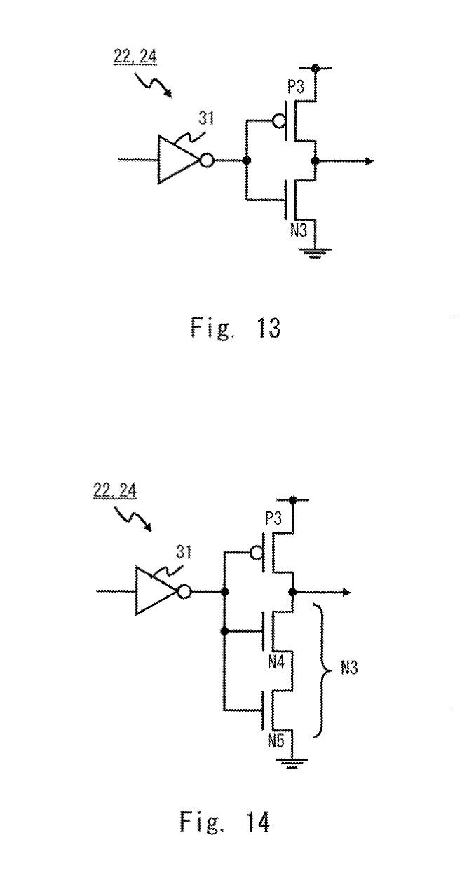

In this exemplary embodiment, the clock multiplexing circuit 11 generates a signal whose voltage and current change with different time rates of change for a rising edge and a falling edge of the transmission signal Dsm. In order to generate such an output waveform, the method for the pre-buffers 22 and 24 to drive the NMOS transistors is varied in this exemplary embodiment. FIG. 13 shows a circuit diagram of the pre-buffers 22 and 24. As shown in FIG. 13, the pre-buffers 22 and 24 each include an inverter 31, a PMOS transistor P3, and an NMOS transistor N3. The inverter 31 inverts the received signal and supplies the inverted signal to the PMOS transistor P3 and the NMOS transistor N3. The PMOS transistor P3 and the NMOS transistor N3 are connected in series between the power supply terminal and the ground terminal, thereby constituting an inverter. In this exemplary embodiment, the current drive capability of the NMOS transistor N3 is set to be lower than that of the PMOS transistor P3. Such adjustment of the current drive capability can be achieved by setting the gate length of the NMOS transistor N3 to be longer than that of the PMOS transistor P3, or by setting the gate width of the NMOS transistor N3 to be smaller than that of the PMOS transistor P3.

FIG. 14 shows another circuit example of the pre-buffers 22 and 24. In the circuit example shown in FIG. 14, the NMOS transistor N3 is composed of a plurality of NMOS transistors (NMOS transistors N4 and N5 in the example shown in FIG. 14) which are connected in serial. This configuration enables adjustment of the current drive capability of the NMOS transistor N3.

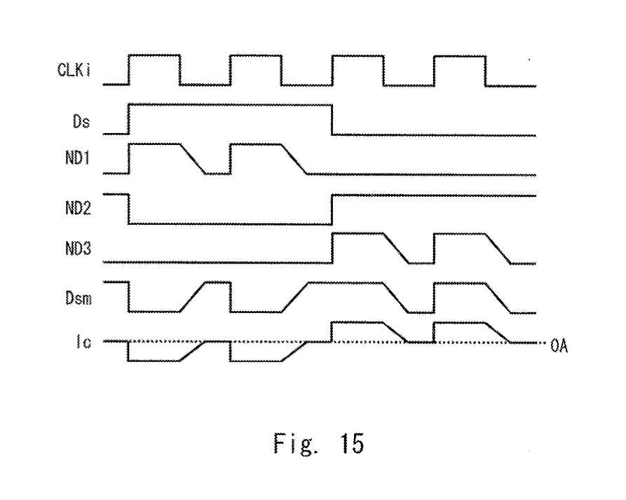

Next, operation of the clock multiplexing circuit 11 will be described in detail. FIG. 15 shows a timing diagram showing the operation of the clock multiplexing circuit 11. As shown in FIG. 15, the clock multiplexing circuit 11 superimposes a pulse signal on the transmission signal Dsm in synchronization with the first clock signal CLKi. For example, when the logic level of the first serial data Ds is a first logic level (e.g., 1, which indicates a high level or a power supply voltage level), the logic level of the transmission signal Dsm is also 1. In this case, the clock multiplexing circuit 11 superimposes a pulse signal (hereinafter, referred to as a negative pulse signal), which has an amplitude in the direction of a second logic level (e.g., 0, which indicates a low level or a ground voltage level) opposite to the logic level of 1, on the transmission signal Dsm. When the logic level of the first serial data Ds is 0 (at the low level or ground voltage level), the logic level of the transmission signal Dsm is also 0. In this case, the clock multiplexing circuit 11 superimposes a pulse signal (hereinafter, referred to as a positive pulse signal), which has an amplitude in the direction opposite to the logic level of 0 (i.e., 1), on the transmission signal Dsm.

In the timing diagram shown in FIG. 15, the rising or falling edges of the transmission signal Dsm are asymmetrical. This is because the falling waveform for the pre-buffers 22 and 24 to drive the NMOS transistors N1 and N2 is more gradual than the rising waveform. By employment of such a driving method, when the positive pulse signal is superimposed on a drive current Ic, which flows from one terminal of the primary coil 12 to the other terminal thereof, the time rate of change at the fall becomes more gradual than that at the rise. Meanwhile, when a negative pulse signal is superimposed on the drive current Ic, the time rate of change upon a fall of the current becomes steeper than that upon a rise of the current.

When transformers are used as AC coupling elements, the magnitude of a potential change that occurs in the secondary coil is determined according to the magnitude of the time differential value (time rate of change) of a current change that occurs in the primary coil. That is, when a steep current change occurs in the primary coil 12, a large potential change occurs in the secondary coil 13. Accordingly, the employment of the method for driving the primary coil 12 according to this exemplary embodiment can suppress a potential change that occurs during a period in which the current change occurring due to the pulse signal is restored to the original state. In other words, according to the method for driving the primary coil 12 of this exemplary embodiment, a potential change on the secondary coil 13 side which occurs due to the polarity of the pulse signal to be transmitted can be increased, thereby suppressing an opposite potential change which occurs when the current is restored to the original state. Thus, in the signal transmission system according to this exemplary embodiment, the reliability of signal transmission is secured.

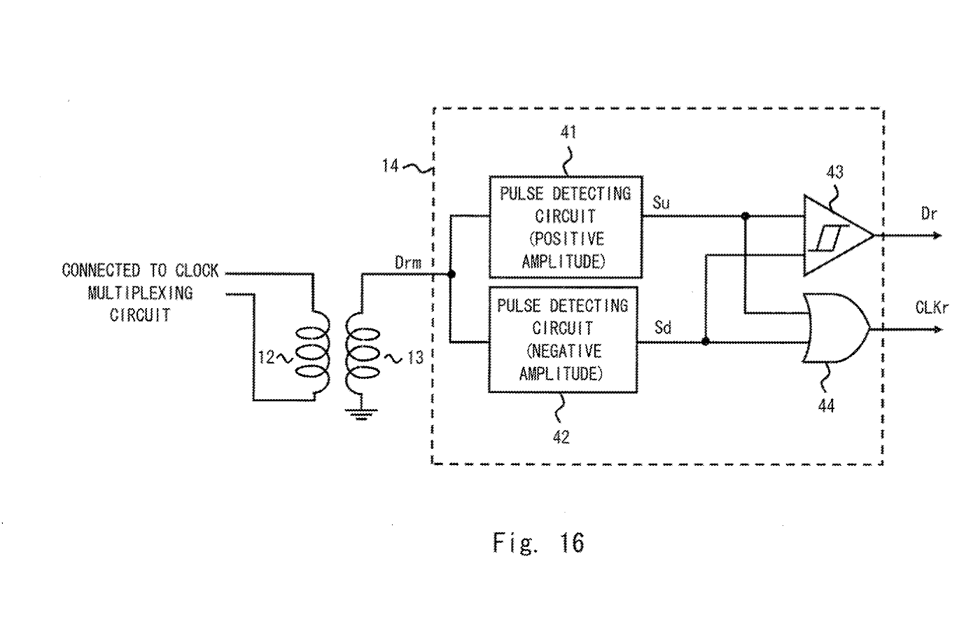

Subsequently, details of the clock data recovery circuit 14 will be described. FIG. 16 shows a block diagram of the clock data recovery circuit 14. As shown in FIG. 16, the clock data recovery circuit 14 includes a first pulse detector 41, a second pulse detector 42, a hysteresis comparator 43, and an OR circuit 44.

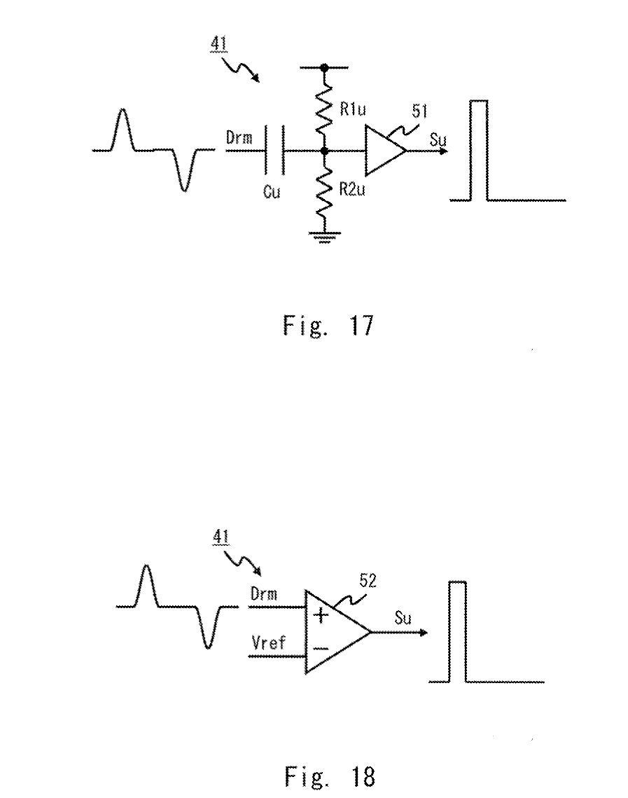

The first pulse detector 41 detects a positive potential change of the reception signal Drm, which occurs at the receiving node connected to the secondary coil 13, and outputs a first detection signal Su. FIGS. 17 and 18 show circuit examples of this first pulse detector 41. In the circuit example shown in FIG. 17, the first pulse detector 41 includes a buffer circuit 51, a capacitor Cu, and resistors R1u and R2u. The buffer circuit 51 receives the reception signal Drm through the capacitor Cu. When the positive potential change of the reception signal Drm exceeds an input threshold of the buffer circuit 51, the buffer circuit 51 outputs the first detection signal Su for maintaining the high level during a period in which the potential change of the reception signal Drm exceeds the input threshold. At this time, the resistors R1u and R2u which are connected in series between the power supply terminal and the ground terminal apply a bias voltage at the input side of the buffer circuit 51. Meanwhile, in the circuit example shown in FIG. 18, the first pulse detector 41 includes a comparator 52. The comparator 52 receives the reception signal Drm at a non-inverting terminal, and receives a reference voltage Vref at an inverting terminal. During a period in which the reception signal Drm exceeds the voltage level of the reference voltage Vref, the comparator 52 outputs the first detection signal Su for maintaining the high level.

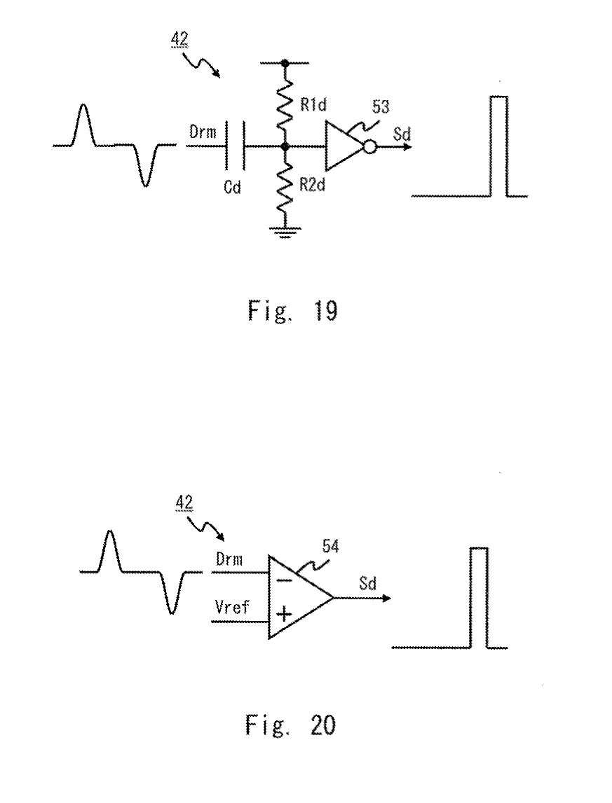

The second pulse detector 42 detects a negative potential change of the reception signal Drm, which occurs at the receiving node connected to the secondary coil 13, and output a second detection signal Sd. FIGS. 19 and 20 show circuit examples of this second pulse detector 42. In the circuit example shown in FIG. 19, the second pulse detector 42 includes an inverting buffer circuit 53, a capacitor Cd, and resistors R1d and R2d. The inverting buffer circuit 53 receives the reception signal Drm through the capacitor Cd. When the positive potential change of the reception signal Drm is smaller than an input threshold of the inverting buffer circuit 53, the inverting buffer circuit 53 outputs the second detection signal Sd for maintaining the high level during a period in which the potential change of the reception signal Drm is lower than the input threshold. At this time, a bias voltage on the input side of the inverting buffer circuit 53 is applied by the resistors R1d and R2d which are connected in series between the power supply terminal and the ground terminal. Meanwhile, in the circuit example shown in FIG. 20, the second pulse detector 42 includes a comparator 54. The comparator 54 receives the reception signal Drm at an inverting terminal that, and receives the reference voltage Vref at a non-inverting terminal. Further, the comparator 54 outputs the second detection signal Sd for maintaining the high level during a period in which the reception signal Drm is lower than the voltage level of the reference voltage Vref.

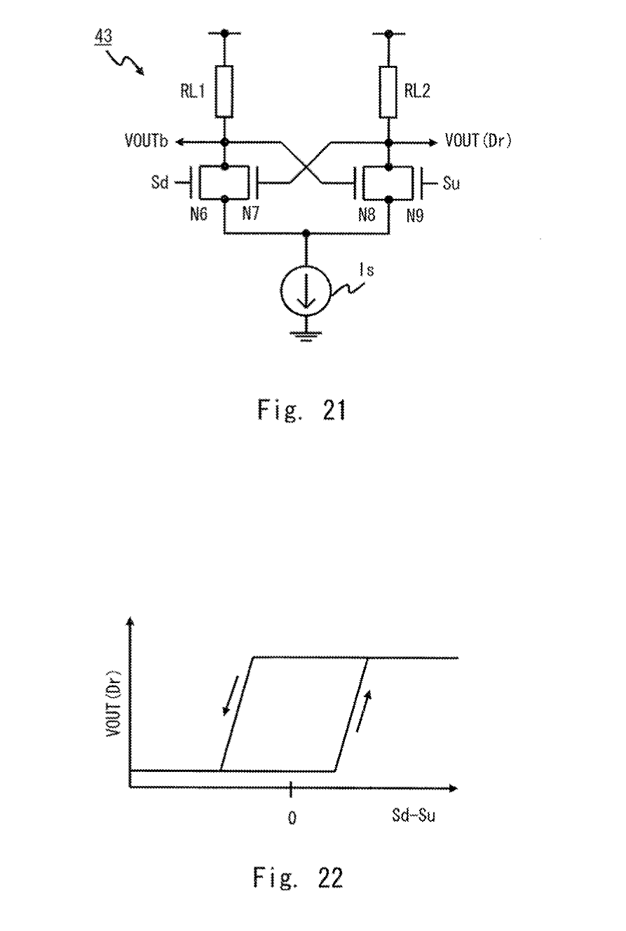

The hysteresis comparator 43 switches the logic level of a signal to be output, according to a polarity of a potential difference between the first detection signal Su and the second detection signal Su. The signal output by the hysteresis comparator 43 serves as the second serial data Dr. FIG. 21 shows a circuit example of the hysteresis comparator 43.

As shown in FIG. 21, the hysteresis comparator 43 includes a current source Is, NMOS transistors N6 to N9, and load resistors RL1 and RL2. The current source Is has one terminal connected to the ground terminal, and supplies an operating current to each of the NMOS transistors N6 to N9 from the other terminal. The gate of the NMOS transistor N6 receives the second detection signal Sd. The gate of the NMOS transistor N7 is connected to a non-inverting output terminal VOUT. The sources of the NMOS transistors N6 and N7 are connected in common and also connected to the other terminal of the current source Is. The drains of the NMOS transistors N6 and N7 are connected in common and also connected to one terminal of the load resistor RL1. A node between the drains of the NMOS transistors N6 and N7 and one terminal of the load resistor RL1 serves as an inverting output terminal VOUTb. The other terminal of the load resistor RL1 is connected to the power supply terminal. The gate of the NMOS transistor N8 is connected to the inverting output terminal VOUTb. The gate of the NMOS transistor N9 receives the first detection signal Su. The sources of the NMOS transistors N8 and N9 are connected in common and also connected to the other terminal of the current source Is. The drains of the NMOS transistors N8 and N9 are connected in common and also connected to one terminal of the load resistor RL2. A node between the drains of the NMOS transistors N8 and N9 and one terminal of the load resistor RL2 serves as the non-inverting output terminal VOUT. The other terminal of the load resistor RL2 is connected to the power supply terminal.

Next, FIG. 22 shows an operating characteristic diagram of the hysteresis comparator 43 shown in FIG. 21. As shown in FIG. 22, when a potential difference (Sd−Su) between the second detection signal Sd and the first detection signal Su is positive and equal to or higher than a predetermined potential difference, the hysteresis comparator 43 sets the logic level of the second serial data Dr, which is output from the non-inverting output terminal, to the high level. Meanwhile, when the potential difference (Sd−Su) between the second detection signal Sd and the first detection signal Su is negative and equal to or higher than the predetermined potential difference, the hysteresis comparator 43 sets the logic level of the second serial data Dr, which is output from the non-inverting output terminal, to the low level. That is, the hysteresis comparator 43 can extract the second serial data Dr as a signal equivalent to the first serial data Ds.

One input terminal of the OR circuit 44 receives the first detection signal Su, and the other input terminal thereof receives the second detection signal Sd. The OR circuit 44 switches the logic level of the second clock signal CLKs according to a result of an OR operation between two input signals. That is, when one of the first detection signal Su and the second detection signal Sd becomes high level, the second clock signal CLKs generated by the OR circuit 44 becomes high level, and in the other periods, the second clock signal CLKs becomes low level. In other words, the OR circuit 44 can extract the second clock signal CLKs as a clock signal equivalent to the first clock signal CLKi superimposed on the transmission signal Dsm.

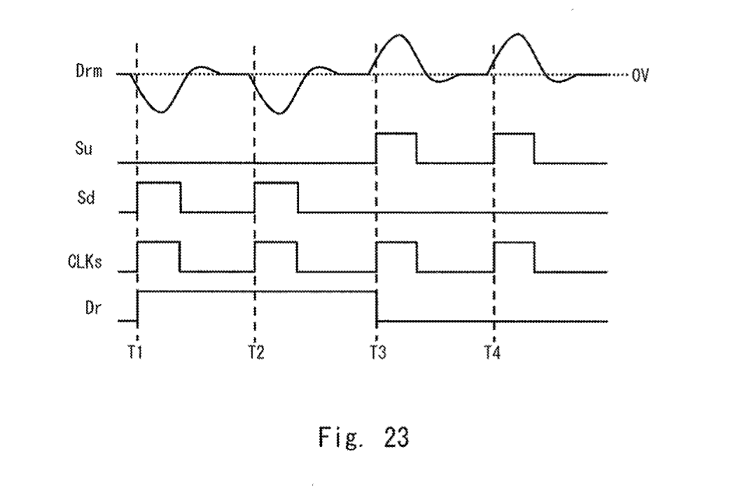

Here, the overall operation of the clock data recovery circuit 14 will be described. FIG. 23 shows a timing diagram showing the operation of the clock data recovery circuit 14. The timing diagram of FIG. 23 shows the operation of the clock data recovery circuit 14 depending on the operation of the clock multiplexing circuit 11 shown in FIG. 15.

As shown in FIG. 23, during a period in which the clock multiplexing circuit 11 outputs the negative pulse signal, the negative drive current Ic flows through the primary coil 12, so that the negative potential change of the reception signal Drm, which is generated by the secondary coil 13 according to the time differential value of the drive current Ic, increases. This negative potential change is detected by the second pulse detector 42. The second pulse detector 42 then sets the second detection signal Sd to the high level during a period in which the negative potential change is equal to or larger than a predetermined potential. During a period in which the negative potential change of the reception signal Drm is large, the first detection signal Su is maintained at the low level. This is because the clock multiplexing circuit 11 controls the rise and fall of the drive current Ic, which flows through the primary coil 12, to be asymmetrical, thereby suppressing an opposite potential change during a period in which the potential change of the reception signal Drm is restored. When the potential difference between the first detection signal Su and the second detection signal Sd is negative and equal to or higher than the predetermined potential at time T1, the hysteresis comparator 43 sets the logic level of the second serial data Dr to the high level. Further, the OR circuit 44 generates a rising edge of the second clock signal CLKs in response to the rise of the second detection signal Sd at times T1 and T2.

As shown in FIG. 23, during a period in which the clock multiplexing circuit 11 outputs the positive pulse signal, the positive drive current Ic flows through the primary coil 12, so that the positive potential change of the reception signal Drm, which is generated by the secondary coil 13 according to the time differential value of the drive current Ic, increases. This positive potential change is detected by the first pulse detector 41. The first pulse detector 41 sets the first detection signal Su to the high level during a period in which the positive potential change is equal to or larger than the predetermined potential. During a period in which the positive potential change of the reception signal Drm is large, the second detection signal Sd is maintained at the low level. This is because the clock multiplexing circuit 11 controls the rise and fall of the drive current Ic, which flows through the primary coil 12, to be asymmetrical, thereby suppressing an opposite potential change during a period in which the potential change of the reception signal Drm is restored. At time T3, when the potential difference between the first detection signal Su and the second detection signal Sd is positive and equal to or higher than the predetermined potential difference, the hysteresis comparator 43 sets the logic level of the second serial data Dr to the low level. Further, the OR circuit 44 generates a rising edge of the second clock signal CLKs in response to the rise of the first detection signal Su at times T3 and T4.

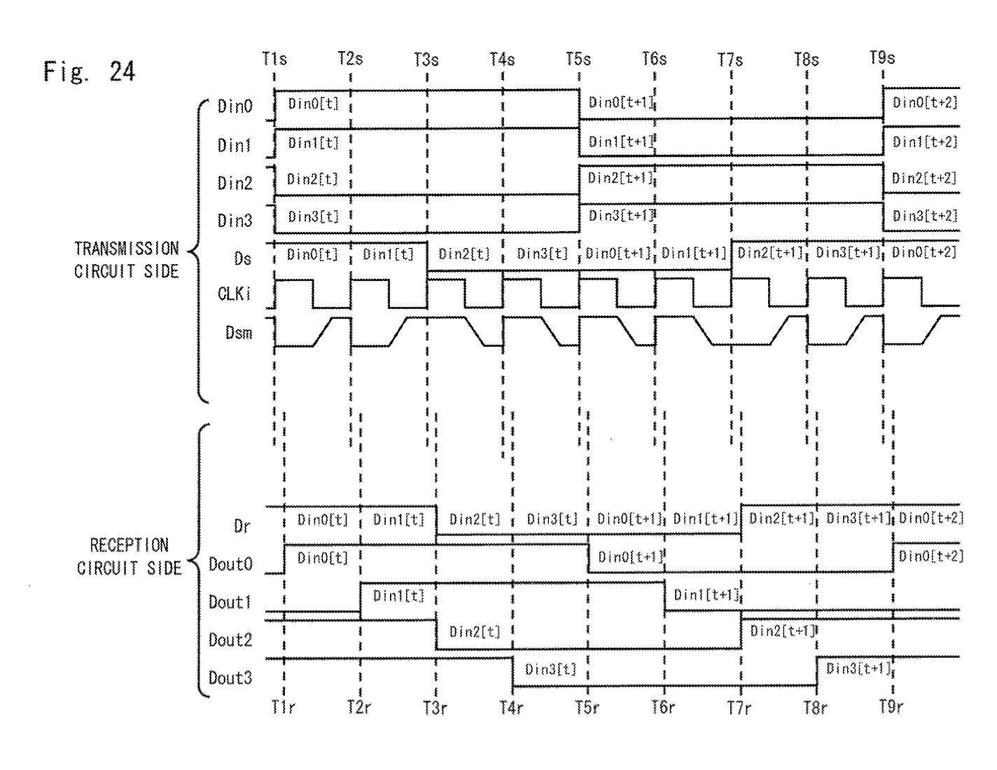

Subsequently, the overall operation of the signal transmission system according to this exemplary embodiment will be described. FIG. 24 shows a timing diagram showing the overall operation of the signal transmission system according to this exemplary embodiment.

In the operation example shown in FIG. 24, at timing T1s, the data Din0 to Din3 serve as data Din0[t] to Din3[t] (t is an integer representing the sequence of data), respectively. Assume herein that the data Din0[t] and Din1[t] are at the high level and the data Din2[t] and data Din3[t] are at the low level, and that the data Din0[t] to Din3[t] are maintained at the same logic level until timing T5s. The first clock signal CLKi has rising edges at timings T1s to T4s.

In response to the rising edges of this first clock signal CLKi, the multiplexer 10 sequentially outputs the data Din0[t] to Din3[t] at timings T1s to T4s. Thus, the first serial data Ds is composed of the data Din0[t] to Din3[t] sequentially arranged. The clock multiplexing circuit 11 having received the first serial data Ds and the first clock signal CLKi outputs the transmission signal Dsm obtained by superimposing the first clock signal CLKi on the first serial data Ds. When the first serial data Ds at the timing when a rising edge of the first clock signal CLKi is input is at the high level, the transmission signal Dsm includes a negative pulse signal. When the first serial data Ds at the timing when a rising edge of the first clock signal CLKi is input is at the low level, the transmission signal Dsm includes a positive pulse signal. Further, the clock multiplexing circuit 11 drives the primary coil 12 by using the negative drive current Ic in response to the negative pulse signal, and drives the primary coil 12 by using the positive drive current Ic in response to the positive pulse signal. At this time, when the negative drive current Ic is output, the time rate of change at a falling edge of each of the pulse signal and the drive current Ic is preferably larger than the time rate of change at a rising edge thereof. Meanwhile, when the positive drive current Ic is output, the time rate of change at a rising edge of each of the pulse signal and the drive current Ic is preferably larger than the time rate of change at a falling edge thereof.

In response to the operation on the transmission circuit 5 side, the secondary coil 13 changes the potential of the reception signal Drm. Then, in response to the potential change of the reception signal Drm, the clock data recovery circuit 14 outputs the second clock signal CLKs and the second serial data Dr. This second clock signal CLKs has rising edges at timings T1r to Tr4 in response to the potential change of the reception signal Drm. The second serial data Dr is switched to data Din0[t] to Din3[t] (data extracted from the reception signal Drm) at timings T1r to Tr4, like the second clock signal CLKs. The demultiplexer 15 switches the output terminal to be selected at a rising edge of the second clock signal CLKs. More specifically, at timing T1r, the demultiplexer 15 selects the output terminal corresponding to the data Dout0 and outputs the data Din0[t] as the data Dout0. At timing T2r, the demultiplexer 15 selects the output terminal corresponding to the data Dout1 and outputs the data Din1[t] as the data Dout1 . At timing T3r, the demultiplexer 15 selects the output terminal corresponding to the data Dout2 and outputs the data Din2[t] as the data Dout2. At timing T4r, the demultiplexer 15 selects the output terminal corresponding to the data Dout3 and outputs the data Din3[t] as the data Dout3. During the period between timing T4r and timing T5r, the data Dout0 to Dout3 serve as the data Din0[t] to Din3[t] included in the first parallel data. Thus, a circuit (not shown) receiving the output of the demultiplexer 15 loads the data Din0[t] to Din3[t], thereby establishing communication.

After that, input of new first parallel data to the multiplexer 10 is started from timing T5s, and operations corresponding to timings T1s to T5s and operations corresponding to timings T1r to T5r are carried out at timings T5s to T9s and at timings T5r to T9r, respectively, thereby executing communication in a subsequent cycle.

As described above, according to the signal transmission system of this exemplary embodiment, the first parallel data to be transmitted through a plurality of channels can be transmitted through a single channel (a single transformer). At this time, in the signal transmission system according to this exemplary embodiment, the first clock signal CLKi is multiplexed with the signal transmitted through a single transformer. Accordingly, the reception circuit 6 can extract the second serial data Dr corresponding to the first serial data Ds and the second clock signal CLKs corresponding to the first clock signal CLKi from the reception signal Drm, which is received through a single transformer, and can reproduce the second parallel data corresponding to the first parallel data from the extracted signal.

That is, in the signal transmission system according to this exemplary embodiment, the parallel data for use with a plurality of channels can be transmitted and received by a single transformer, thereby drastically reducing the circuit area of the semiconductor chip.

In the signal transmission system according to this exemplary embodiment, the first clock signal CLKi is further multiplexed with the first serial data Ds, which is generated by time-division multiplexing the first parallel data, thereby generating the transmission signal Dsm. Thus, the signal transmission system according to this exemplary embodiment eliminates the need for channels to transmit the clock signal, and is capable of transmitting and receiving the data signal and the clock signal by using a single transformer. In short, the semiconductor system according to this exemplary embodiment can drastically reduce the circuit area of the semiconductor chip.

In the signal transmission system according to this exemplary embodiment, the clock multiplexing circuit 11 for use in multiplexing the clock signal with the first serial data can be implemented by a circuit with several gates. Additionally, the clock data recovery circuit 14 for use in extracting the multiplexed second clock signal CLKs from the reception signal Drm can be composed of over ten circuit elements. That is, according to the signal transmission system according to this exemplary embodiment, the multiplexing and extraction of the clock signal can be implemented by a small circuit, thereby reducing the chip area.

In the signal transmission system according to this exemplary embodiment, the reception circuit 6 can generate the second clock signal for converting the second serial data into the second parallel data without using a PLL circuit or a DLL circuit. Accordingly, the signal transmission system according to this exemplary embodiment can drastically reduce the circuit area of the second semiconductor chip mounted with the reception circuit 6.

In the signal transmission system according to this exemplary embodiment, the second clock signal CLKs for use in converting the second serial data Ds into the second parallel data is multiplexed with the second serial data. Meanwhile, the serial communication method of related art uses a PLL circuit or the like to generate a clock signal. The PLL circuit or the like requires a time for the clock signal to be synchronized with serial data (the time is referred to as a clock time). However, the PLL circuit or the like is not used to generate the second clock signal CLKs, which results in a reduction of a clock period generated in the PLL circuit or the like. That is, the signal transmission system according to this exemplary embodiment can reduce a delay time which occurs by the time when processing for the received reception signal Drm is started.

In serial communication, it is necessary to identify a first bit of the received serial data. Meanwhile, the signal transmission system according to this exemplary embodiment converts the second serial data Dr into the second parallel data by using the second clock signal CLKs, which is multiplexed with the second serial data Dr, thereby eliminating the need to identify the first bit of the serial data.

In the signal transmission system according to this exemplary embodiment, the clock multiplexing circuit 11 and the clock data recovery circuit 14 operate only in response to the input signal, and do not always operate, unlike a PLL circuit and a DLL circuit. For this reason, the signal transmission system according to this exemplary embodiment achieves a reduction in power consumption. Moreover, the clock multiplexing circuit 11 and the clock data recovery circuit 14 are implemented by a small number of circuit elements, thereby achieving a further reduction in power consumption.

The communication through transformers has constraints such as a limitation of frequency bands of signals that can be transmitted by the transformer. This limitation is necessary to maintain the quality of signals used for the purposes other than the communication through the transformer, such as an operating clock for the first and second semiconductor chips. For this reason, in Patent Literatures 1 to 8, processing such as modulation of a base band signal at a specific frequency is performed, and communication using the base band signal is carried out after the processing. On the other hand, in the signal transmission system according to this exemplary embodiment, the first clock signal CLKi is multiplexed with the first serial data Ds to be transmitted, thereby eliminating the need to separately perform modulation processing for shifting the communication frequency band. In short, the signal transmission system according to this exemplary embodiment can reduce the semiconductor chip area.

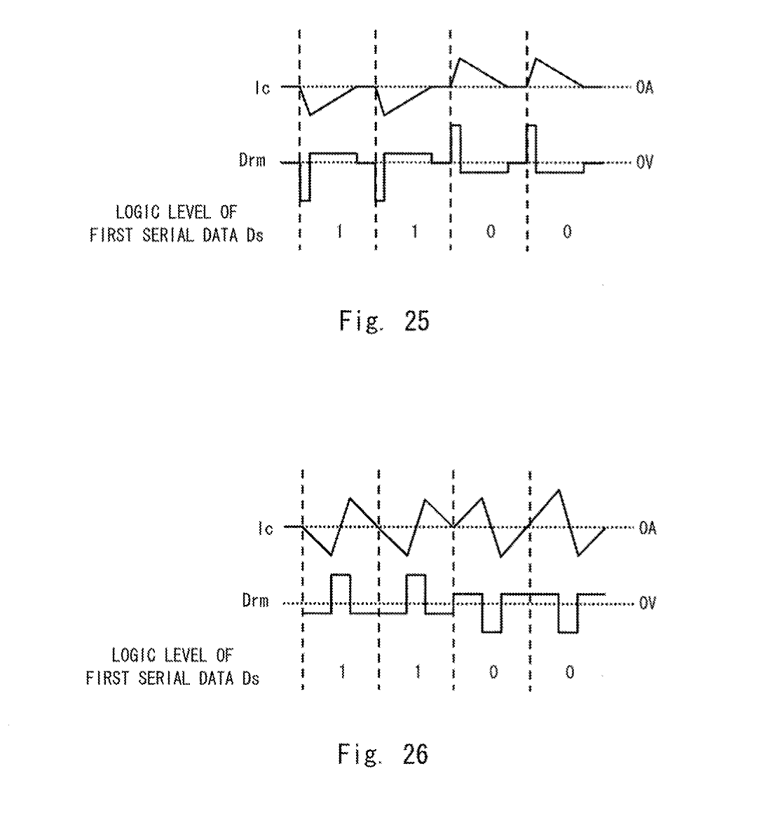

Note that the output of the clock multiplexing circuit 11 according to the above exemplary embodiment may have waveforms as shown in FIGS. 25 and 26, in addition to the waveform shown in FIG. 15. In the exemplary output waveform shown in FIG. 25, when the value of the first serial data Ds is 1, the drive current Ic is allowed to rapidly fall and then gradually rise, without providing a period for holding the current value. When the value of the first serial data Ds is 0, the drive current Ic is allowed to rapidly rise and then gradually fall, without providing a period for holding the current value. Shaping the drive current Ic into such a waveform allows the reception signal Drm to be formed into a pulse-like waveform. In the exemplary output waveform shown in FIG. 26, when the value of the first serial data Ds is 1, the drive current Ic is allowed to gradually fall and then rapidly rise, and the current value is gradually decreased to 0 again. When the value of the first serial data Ds is 0, the drive current Ic is allowed to gradually rise and then rapidly fall, and the current value is gradually decreased to 0 again. Shaping the drive current Ic into such a waveform allows the pulse signal in the reception signal Drm to be positioned in the vicinity of the center of one data transmission section.

### Second Exemplary Embodiment

A signal transmission system according to a second exemplary embodiment will be described. Hereinafter, the elements described in the signal transmission system according to the first exemplary embodiment are denoted by the same reference numerals as those used to describe the signal transmission system according to the first exemplary embodiment, and the description thereof is omitted.

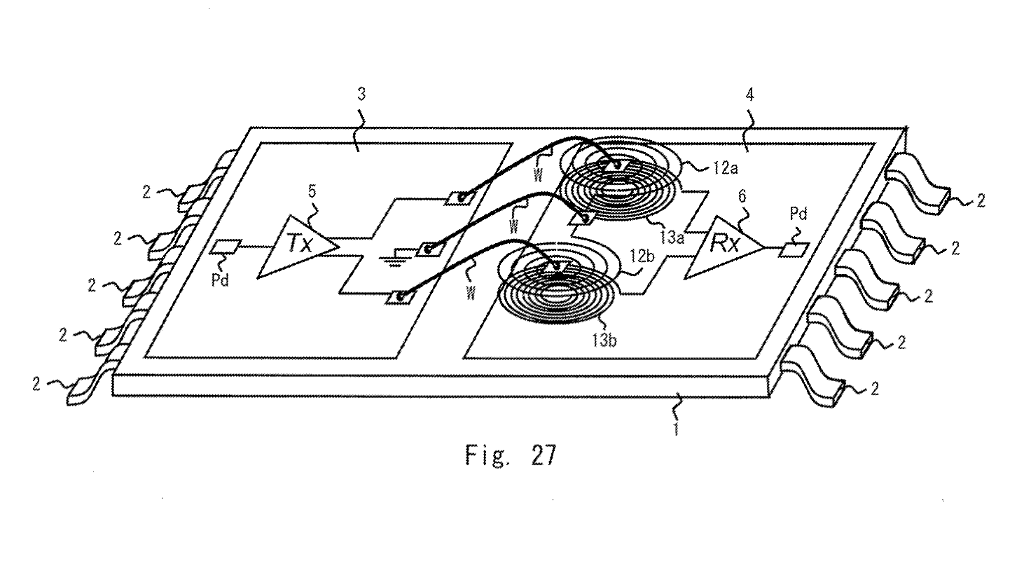

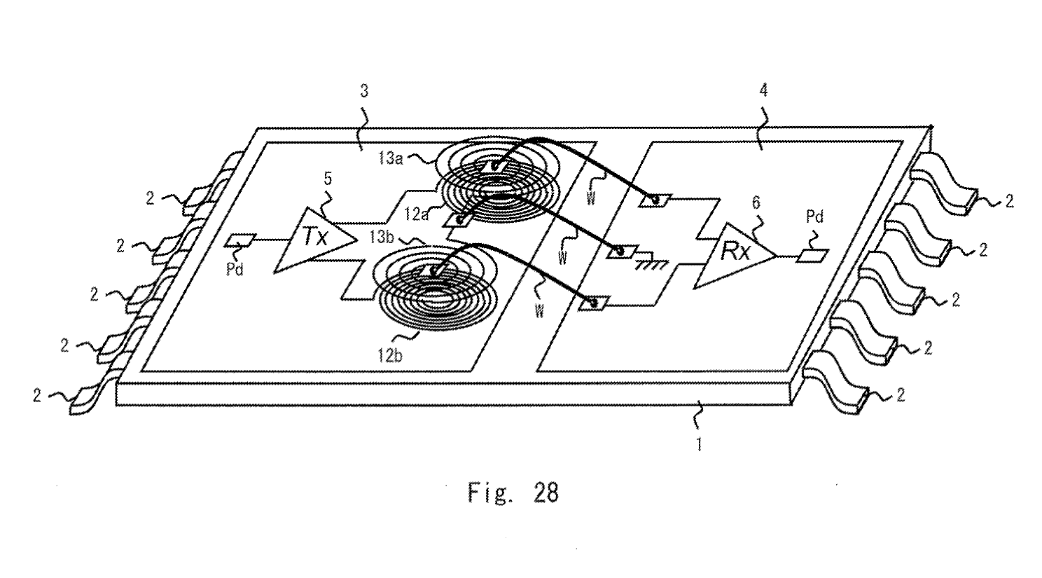

First, FIGS. 27 and 28 show schematic views each illustrating a mounted state of the signal transmission system according to the second exemplary embodiment. In the mounting example shown in FIG. 27, two transformers are provided on the side of the second semiconductor chip 4. In the mounting example shown in FIG. 28, two transformers are provided on the side of the first semiconductor chip 3. The two transformers are composed of a first transformer including a first primary coil 12a and a first secondary coil 13a; and a second transformer including a second primary transformer 12b and a second secondary transformer 13b. The coils constituting the two transformers have one terminal connected to the ground terminal and the other terminal connected to the corresponding transmitting node of the transmission circuit 5 or the corresponding receiving node of the reception circuit 6.

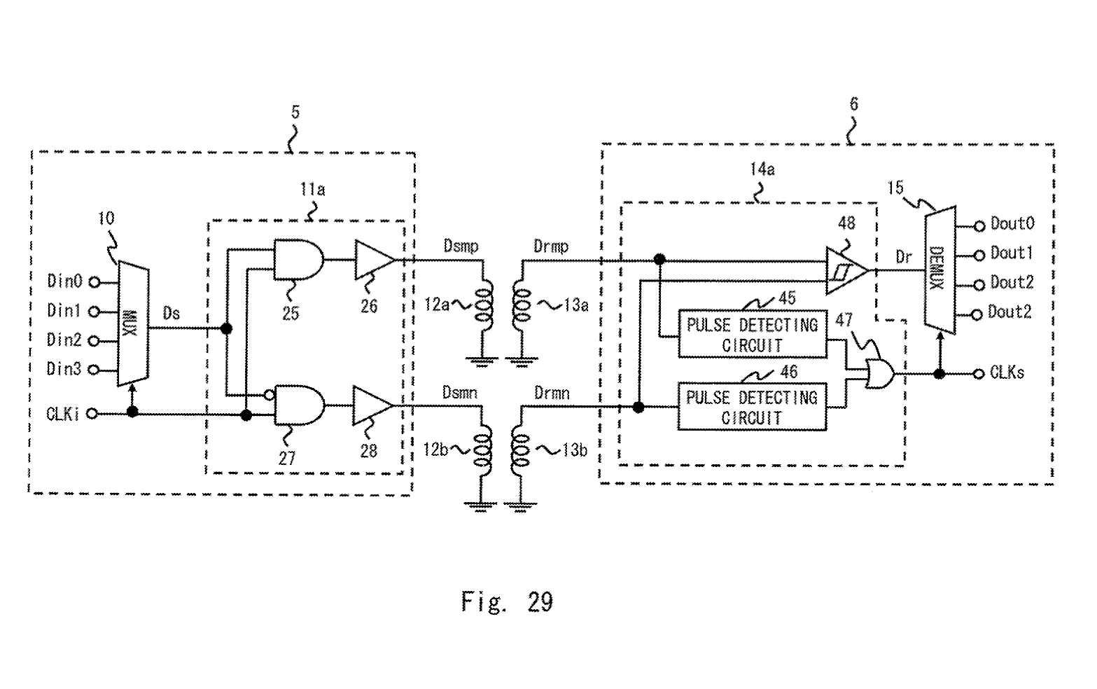

Next, FIG. 29 shows a block diagram of the signal transmission system according to the second exemplary embodiment. As shown in FIG. 29, in the signal transmission system according to the second exemplary embodiment, the transmission circuit 5 includes the multiplexer 10 and a clock multiplexing circuit 11a. The clock multiplexing circuit 11a is a modified example of the clock multiplexing circuit 11 of the first exemplary embodiment. When the logic level of the first serial data Ds is 1, the clock multiplexing circuit 11 a drives the first primary transformer 12a. When the logic level of the first serial data Ds is 0, the clock multiplexing circuit 11a drives the second primary transformer 12b.

The clock multiplexing circuit 11a includes an AND circuit 25, buffer circuits 26 and 28, and an AND circuit 27 having an inverting input. One input terminal of the AND circuit 25 is supplied with the first serial data Ds, and the other input terminal thereof is supplied with the first clock signal CLKi. The AND circuit 25 outputs a result of an AND operation between two input signals to the buffer circuit 26. The buffer circuit 26 outputs a transmission signal Dsmp to the first primary transformer 12a according to the output signal from the AND circuit 25, and drives the first primary transformer 12a. An inverting input terminal (one terminal) of the AND circuit 27 having an inverting input is supplied with the first serial data Ds, and the other input terminal thereof is supplied with the first clock signal CLKi. The AND circuit 27 having an inverting input outputs a result of an AND operation between the inverted value of the first serial data Ds and the logical value of the first clock signal CLKi to the buffer circuit 28. The buffer circuit 28 outputs a transmission signal Dsmn to the second primary transformer 12b according to the output signal of the AND circuit 27 having an inverting input, and drives the second primary transformer 12b.

As shown in FIG. 29, in the signal transmission system according to the second exemplary embodiment, the reception circuit 6 includes a clock data recovery circuit 14a and the demultiplexer 15. The clock data recovery circuit 14a is a modified example of the clock data recovery circuit 14 of the first exemplary embodiment. The clock data recovery circuit 14a extracts the second serial data Dr and the second clock signal CLKs from a reception signal Drmp received through the first secondary transformer 13a and a reception circuit Drmn received through the second secondary transformer 13b.

The clock data recovery circuit 14a includes pulse detectors 45 and 46, an OR circuit 47, and a hysteresis comparator 48. The pulse detectors 45 and 46 each correspond to the first pulse detector 41 according to the first exemplary embodiment. That is, the pulse detectors 45 and 46 detect a positive potential change generated in the reception signals Drmp and Drmn, and output first and second detection signals, respectively. Assume that the pulse detector 45 outputs the first detection signal and the pulse detector 46 outputs the second detection signal. The OR circuit 47 switches the logic level of the second clock signal CLKs based on a result of an AND operation between the first and second detection signals. The hysteresis comparator 48 corresponds to the hysteresis comparator 43 of the first exemplary embodiment. In the second exemplary embodiment, the hysteresis comparator 48 directly receives the reception signals Drmp and Drmn. The hysteresis comparator 48 switches the logic level of the second serial data Dr based on the polarity and value of a potential difference between the reception signals Drmp and Drmn.

Subsequently, operation of the signal transmission system according to the second exemplary embodiment will be described. In the signal transmission system according to the second exemplary embodiment, the time-division multiplexing of the first parallel data and the method of generating the second parallel data from the second serial data are the same as those of the first exemplary embodiment. Accordingly, only the parts involving transmission and reception of signals through the transformers are described below.

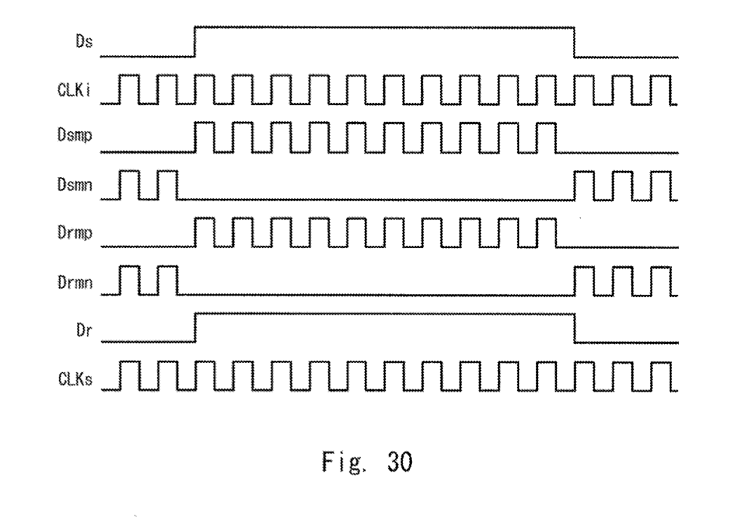

FIG. 30 shows a timing diagram showing the operation of the signal transmission system according to the second exemplary embodiment. As shown in FIG. 30, in the signal transmission system according to the second exemplary embodiment, during a period in which the logic level of the first serial data Ds is 0, a pulse signal synchronous with the first clock signal CLKi is generated only in the transmission signal Dsmn, and during a period in which the logic level of the first serial data Ds is 1, a pulse signal synchronous with the first clock signal CLKi is generated only in the transmission signal Dsmp.

In the reception circuit 6 having receiving the transmission signals Dsmn and Dsmp, potential changes of the reception signals Drmp and Drmn respectively corresponding to the transmission signals Dsmp and Dsmn are generated in the first secondary transformer 13a and the second secondary transformer 13b. During a period in which a potential change is generated in the reception signal Drmn, the clock data recovery circuit 14a sets the logic level of the second serial data Dr to 0, and during a period in which a potential change is generated in the reception signal Drmp, the clock data recovery circuit 14a sets the logic level of the second serial data Dr to 1. That is, in the second exemplary embodiment, the data recovery circuit 14a transmits serial data having a logic level of 1 by using the first transformer, and transmits serial data having a logic level of 0 by using the second transformer. Further, the clock data recovery circuit 14a synthesizes the pulse signals extracted from the potential changes generated in the reception signals Drmp and Drmn, thereby generating the second clock signal CLKs.

As described above, in the second exemplary embodiment, serial data having a logic level of 1 is transmitted using the first transformer, and serial data having a logic level of 0 is transmitted using the second transformer. The use of different transmission channels depending on the logic level of the data to be transmitted facilitates the configuration of the clock multiplexing circuit 11a. In the first exemplary embodiment, the rise and fall of the drive current Ic are set to be asymmetrical so as to prevent a signal transmission error. In the second exemplary embodiment, however, all the pulse signals included in the transmission signals Dsmp and Dsmn have positive amplitudes. Accordingly, also in the reception-side circuit, it is only necessary to detect the positive potential change. In sum, in signal transmission system according to the second exemplary embodiment, the reception circuit 6 does not operate in response to the negative potential change of the reception signals, which makes it possible to prevent a signal transmission error without the need of controlling the time rate of change upon a rise and a fall of the drive current Ic.

### Third Exemplary Embodiment

A signal transmission system according to a third exemplary embodiment will be described. Hereinafter, the elements described in the signal transmission systems according to the first and second exemplary embodiments are denoted by the same reference numerals as those used to describe the signal transmission systems according to the first and second exemplary embodiments, and the description thereof is omitted.

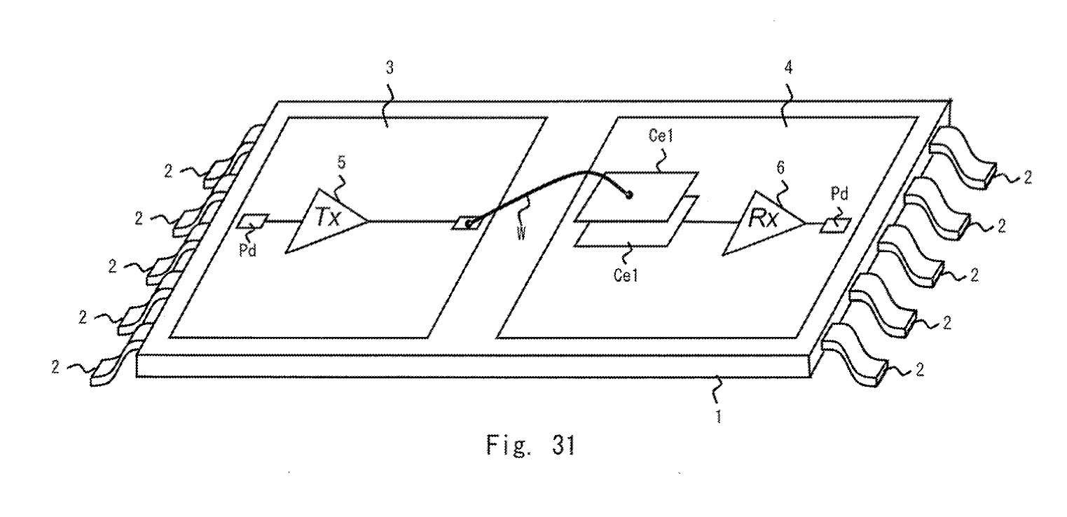

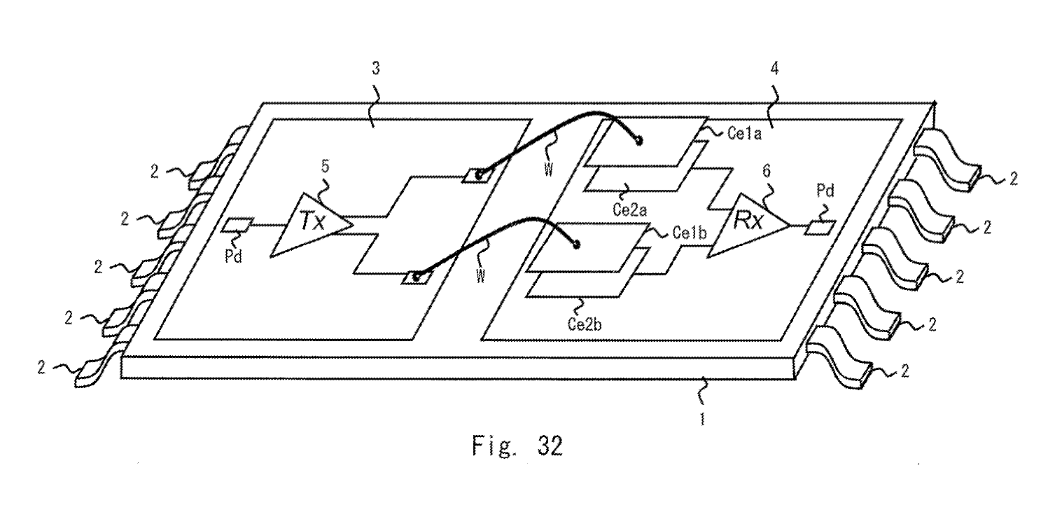

First, FIGS. 31 and 32 show schematic views each illustrating a mounted state of the signal transmission system according to the third exemplary embodiment. In the mounting example shown in FIG. 31, the transformers in the mounting example of the signal transmission system shown in FIG. 1 are replaced with capacitors. In the mounting example shown in FIG. 32, the transformers in the mounting example of the signal transmission system shown in FIG. 27 are replaced with capacitors. That is, the signal transmission system according to the third exemplary embodiment is an example using capacitors as AC coupling elements.

In the capacitors for signal transmission in the signal transmission system according to the third exemplary, metal lines (electrodes Ce1 and Ce2 shown in FIG. 31 and electrodes Ce1a, Ce1b, Ce1a, and Ce2b shown in FIG. 32) formed in different wiring layers are used as two electrodes for the capacitors, and an insulator (for example, an interlayer insulating film) filled between the metal lines is used as a dielectric.

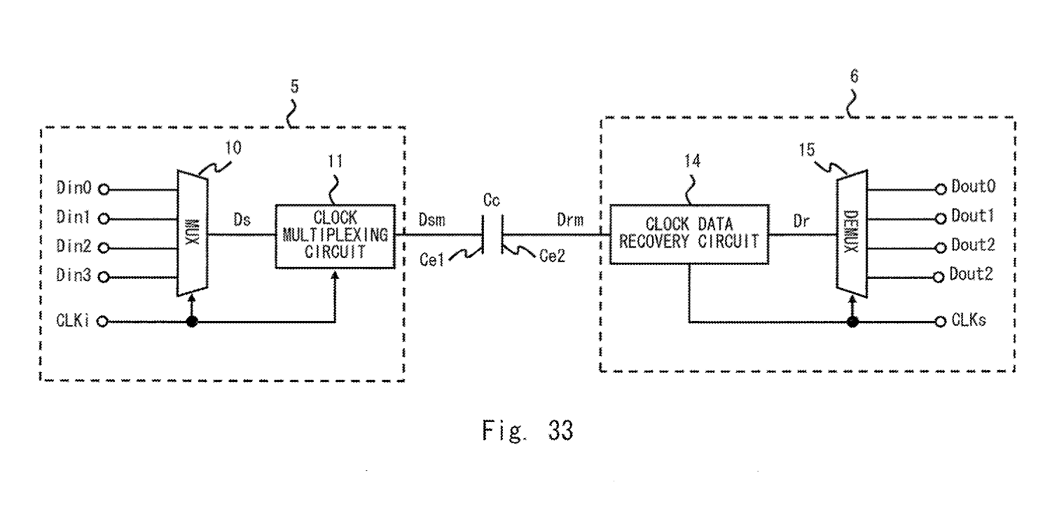

Subsequently, FIG. 33 shows a block diagram of the signal transmission system according to the third exemplary embodiment. As shown in FIG. 33, in the signal transmission system according to the third exemplary embodiment, the transmitting node of the clock multiplexing circuit 11 is connected to the first electrode Ce1 of a capacitor Cc, and the receiving node of the clock data recovery circuit 14 is connected to the second electrode Ce2 of the capacitor Cc. The block diagram shown in FIG. 33 corresponds to the mounting example shown in FIG. 31. In the circuit corresponding to the mounting example shown in FIG. 32, the transformers of the signal transmission system shown in FIG. 29 may be replaced with capacitors in the same manner as in the block diagram shown in FIG. 33.

In this manner, even when the transmission circuit 5 and the reception circuit 6 are connected together as the AC coupling elements, a voltage fluctuation of the transmission signal Dsm output by the clock multiplexing circuit 11 can be transmitted to the reception circuit 6 as the reception signal Drm. That is, also in the signal transmission system illustrated in the third exemplary embodiment, a reduction in circuit area, a reduction in power consumption, and an increase in speed of signal transmission processing can be achieved as in the first exemplary embodiment. Moreover, the use of two capacitors Cc as in the second exemplary embodiment makes it possible to prevent a signal transmission error.

### Fourth Exemplary Embodiment

A signal transmission system according to a fourth exemplary embodiment will be described. Hereinafter, the elements described in the signal transmission system according to the first exemplary embodiment are denoted by the same reference numerals as those used to describe the signal transmission system according to the first exemplary embodiment, and the description thereof is omitted.

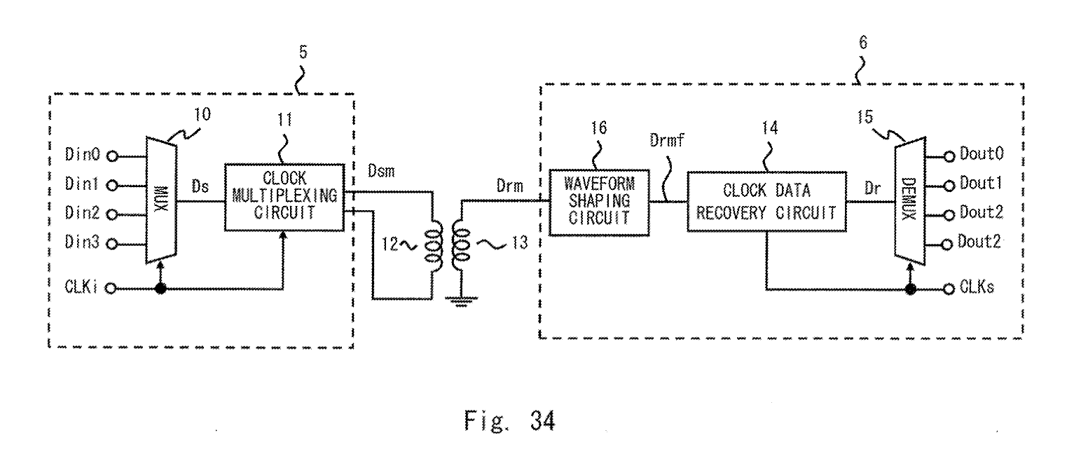

First, FIG. 34 shows a block diagram of the signal transmission system according to the fourth exemplary embodiment. As shown in FIG. 34, the signal transmission system according to the fourth exemplary embodiment has a configuration in which a waveform shaping circuit 16 is added to the reception circuit 6 of the signal transmission system according to the first exemplary embodiment. The waveform shaping circuit 16 is provided between a terminal on the side of the receiving node of the secondary coil 13 and the clock data recovery circuit 14. The waveform shaping circuit 16 is a circuit that holds a peak value of a potential change generated in the reception signal Drm for a predetermined period.

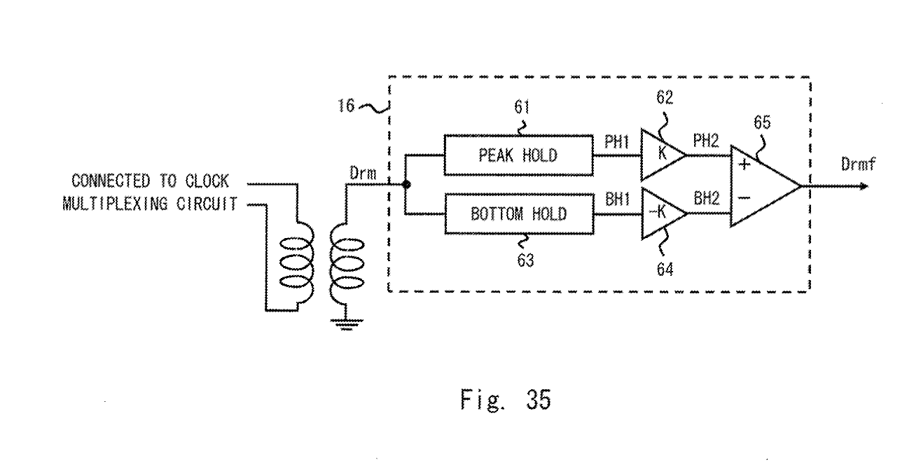

FIG. 35 shows a detailed block diagram of the waveform shaping circuit 16. As shown in FIG. 35, the waveform shaping circuit 16 includes a peak hold circuit 61, a buffer circuit 62, a bottom hold circuit 63, an inverting buffer circuit 64, and a differential amplifier 65. The peak hold circuit 61 receives the reception signal Drm from the terminal on the side of the receiving node of the secondary coil 13, and outputs a first peak hold signal PH1 for holding a peak value of a positive potential change of the reception signal Drm for a predetermined period. The buffer circuit 62 amplifies the first peak hold signal PH1 and outputs a second peak hold signal PH2. The bottom hold circuit 63 receives the reception signal Drm from one terminal of the secondary coil 13, and outputs a first bottom hold signal BH1 for holding a peak value of a negative potential change of the reception signal Drm for a predetermined period. The inverting buffer circuit 64 inverts and amplifies the first bottom hold signal BH1 and outputs a second bottom hold signal BH2. The differential amplifier 65 amplifies a potential difference between the second peak hold signal PH2 and the second bottom hold signal BH2, and outputs a shaped reception signal Drmf. This shaped reception signal Drmf is input to the clock data recovery circuit 14.

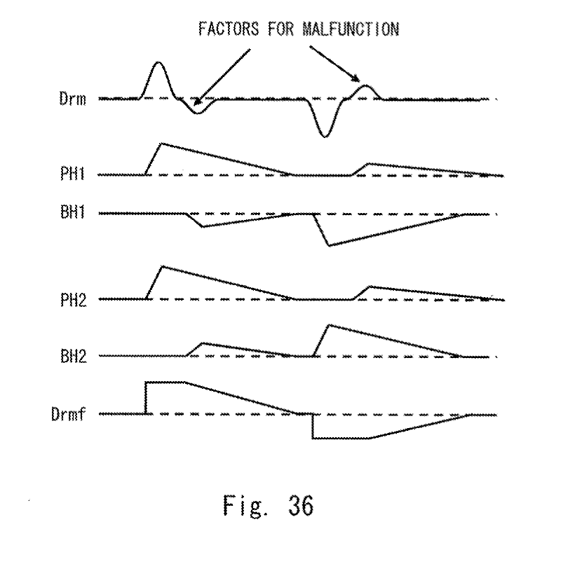

Subsequently, operation of the waveform shaping circuit 16 will be described in detail. FIG. 36 shows a timing diagram illustrating the operation of the waveform shaping circuit 16. As shown in FIG. 36, the reception signal Drm received through the secondary coil 13 causes a small negative potential change subsequent to a large positive potential change. Further, the reception signal Drm causes a small positive potential change subsequent to a large negative potential change. This is because the amount of potential change and the fluctuation direction of the reception signal Drm are determined by the time differential quantity of the drive current Ic generated by the pulse signal of the transmission signal Dsm. When the reception signal Drm is input to the clock data recovery circuit 14, there is a possibility of causing malfunction in the clock data recovery circuit 14 due to a small positive potential change or a small negative potential change.

In the fourth exemplary embodiment, however, such a malfunction can be prevented by providing the waveform shaping circuit 16. As shown in FIG. 36, the first peak hold signal PH1 output by the peak hold circuit 61 follows the potential change of the reception signal Drm until the reception signal Drm reaches the peak value, and then, the voltage of the first peak hold signal PH1 gradually decreases. That is, the first peak hold signal PH1 holds the positive potential change, which is caused in the reception signal Drm, for a predetermined period. Further, the first bottom hold signal BH1 output by the bottom hold circuit 63 follows the potential change of the reception signal Drm until the reception signal Drm reaches the peak value, and then, the voltage of the first bottom hold signal BH1 gradually increases. That is, the first bottom hold signal BH1 holds the negative potential change, which is caused in the reception signal Drm, for a predetermined period.

The waveform shaping circuit 16 amplifies the first peak hold signal PH1 to generate the second peak hold signal PH2, and inverts and amplifies the polarity of the first bottom hold signal BH1 to generate the second bottom hold signal. As a result, a difference in absolute value between the positive potential change and the negative potential change which are caused in the reception signal Drm is given to the differential amplifier 65. The differential amplifier 65 amplifies the difference in absolute value and outputs the shaped reception signal Drmf. Thus, the shaped reception signal Drmf becomes a stable signal having a pulse width wider than that of the reception signal Drm, and the operation of the clock data recovery circuit 14 connected to the subsequent stage is stabilized.

As described above, in the signal transmission system according to the fourth exemplary embodiment, the reception circuit 6 is capable of performing data processing based on the shaped reception signal Drmf, which leads to an improvement in the reliability of communication as compared to the signal transmission systems according to the first to third exemplary embodiments.

### Fifth Exemplary Embodiment

A signal transmission system according to a fifth exemplary embodiment will be described. Hereinafter, the elements described in the signal transmission system according to the first exemplary embodiment are denoted by the same reference numerals as those used to describe the signal transmission system according to the first exemplary embodiment, and the description thereof is omitted.

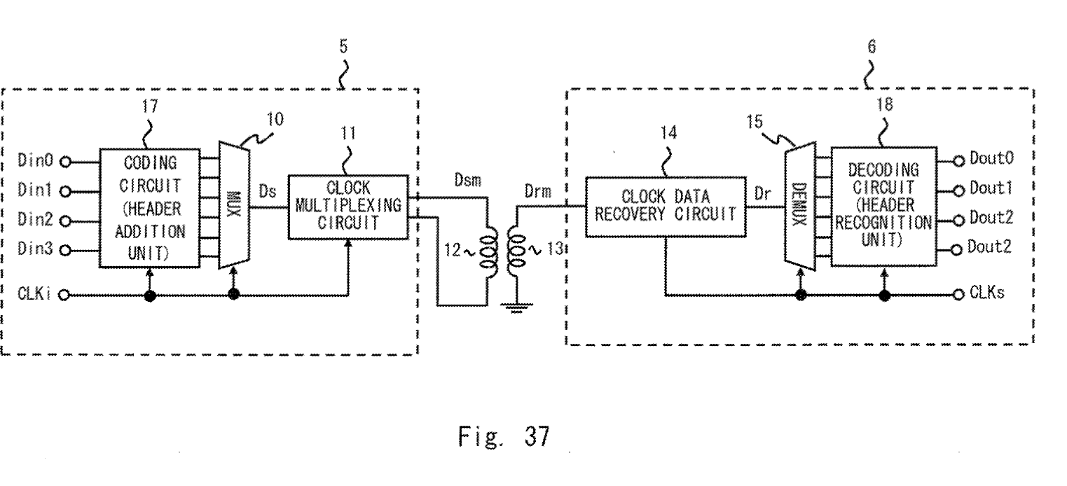

FIG. 37 shows a block diagram of the signal transmission system according to the fifth exemplary embodiment. As shown in FIG. 37, the signal transmission system according to the fifth exemplary embodiment has a configuration in which an encoding circuit 17 and a decoding circuit 18 are added to the signal transmission system according to the first exemplary embodiment. The encoding circuit 17 is provided between the plurality of input terminals, which respectively receive the data Din0 to Din3, and the multiplexer 10. The encoding circuit 17 performs encoding processing based on the data Din0 to Din3, which are respectively input through the input terminals, and generates header information by the encoding processing. Further, the encoding circuit 17 outputs the header information and the data Din0 to Din3 to a multiplexer. As is apparent from the example of FIG. 37, the encoding circuit 17 has four inputs and six outputs and is provided with 2-bit header information. The multiplexer 10 time-division multiplexes the header information and the data Din0 to Din3, thereby generating the first serial data Ds. For the encoding processing performed by the encoding circuit 17, 8B10B encoding or the like may be used.

The decoding circuit 18 is provided between the demultiplexer 15 and the output terminals for the data Dout0 to Dout3. The decoding circuit 18 performs decoding processing on the second parallel data output from the demultiplexer 15, and analyzes the header information obtained from the result of the decoding processing. Based on the analysis result, the data Din0, which is head data, is detected. The decoding circuit 18 outputs the detected head data (data Din0) as the data Dout0, and also outputs the data Din1 to Din3 as the respectively corresponding data Dout1 to Dout3. As is apparent from the example of FIG. 37, since the decoding circuit 18 has six inputs and four outputs, the data Din0 is detected based on 2-bit header information.

As described above, in the signal transmission system according to the fifth exemplary embodiment, the provision of the encoding circuit 17 and the decoding circuit 18 facilitates the detection of the head data of serial data. In order to identify the head of serial data in the serial communication, the communication is typically stopped once at a delimiter, and the next serial data is transmitted after stopping the communication for a predetermined period. Meanwhile, the signal transmission system according to the fifth exemplary embodiment is capable of identifying the head data of serial data based on the header information. This eliminates the need to provide the period in which the communication is stopped.

### Sixth Exemplary Embodiment

A signal transmission system according to a sixth exemplary embodiment will be described. Hereinafter, the elements described in the signal transmission system according to the first exemplary embodiment are denoted by the same reference numerals as those used to describe the signal transmission system according to the first exemplary embodiment, and the description thereof is omitted.

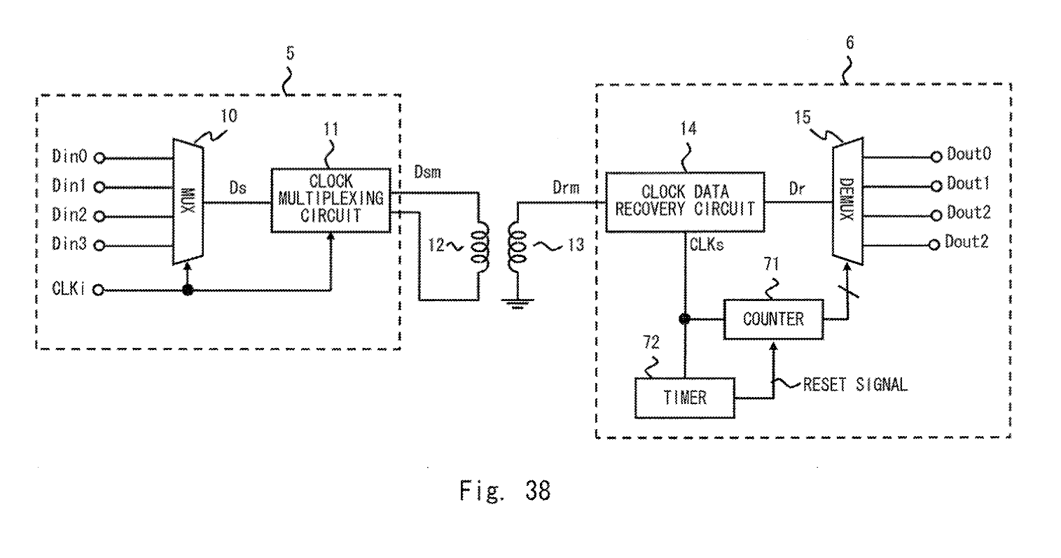

FIG. 38 shows a block, diagram of the signal transmission system according to the sixth exemplary embodiment. As shown in FIG. 38, the signal transmission system according to the sixth exemplary embodiment has a configuration in which a counter 71 and a timer 72 are added to the signal transmission system according to the first exemplary embodiment. The counter 71 counts the number of clocks of the second clock signal CLKs output by the clock data recovery circuit 14, and outputs the count value. In this exemplary embodiment, the demultiplexer 15 selects an output terminal as an output destination of the second serial data according to the count value. The timer 72 measures the length of a period (non-signal period) in which the second clock signal CLKs is maintained at the low level, and outputs a reset signal to the counter 71 when the non-signal period is equal to or longer than a predetermined length. Upon receiving the reset signal, the counter 71 resets the count value to an initial value.

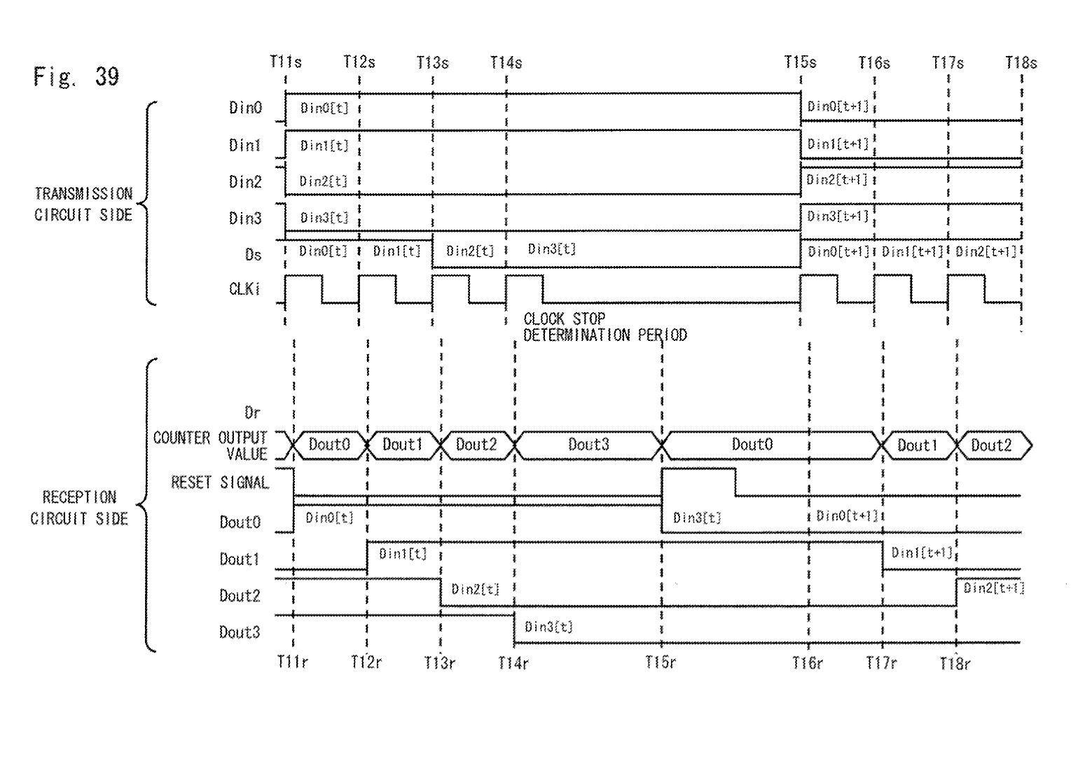

Here, operation of the signal transmission system including the counter 71 and the timer 72 is described. FIG. 39 shows a timing diagram showing the operation of the signal transmission system including the counter 71 and the timer 72. In the timing diagram shown in FIG. 39, the non-signal period representing a delimiter of serial data is provided in the operation of the signal transmission system according to the first exemplary embodiment shown in FIG. 24.

As shown in FIG. 39, in the signal transmission system according to the sixth exemplary embodiment, the count value output by the counter 71 is counted up in response to a rising edge of the second clock signal CLKs. Upon completion of transmission of the data Din0[t] to Din3[t], the transmission circuit 5 stops the first clock signal (fixed to the low level). Accordingly, also in the reception circuit 6, the second clock signal CLKs is finally stopped (fixed to the low level) at the rising edge, which corresponds to timing T14r, of the second clock signal CLKs. At this time, in the signal transmission system according to the sixth exemplary embodiment, the timer 72 starts operation from timing T14r, and the timer 72 outputs the reset signal (set to the high level) at timing T15r. Further, the counter 71 resets the count value in response to a rising edge of the reset signal. The reset count value is a value corresponding to the data Dout0. After that, the signal transmission system according to the sixth exemplary embodiment starts communication in a subsequent cycle from timing T15s.

As described above, in the signal transmission system according to the sixth exemplary embodiment, the timer 72 detects the length of the non-signal period of the second clock signal CLKs representing a delimiter of the serial data, thereby resetting the output terminal selected by the demultiplexer 15. This makes it possible to reliably identify the head data of the serial data without using any data for detecting a delimiter of the serial data. That is, the signal transmission system according to the sixth exemplary embodiment can improve the reliability of communication of serial data only by adding the counter 71 and the timer 72.

### Seventh Exemplary Embodiment

A signal transmission system according to a seventh exemplary embodiment will be described. Hereinafter, the elements described in the signal transmission systems according to the first and sixth exemplary embodiments are denoted by the same reference numerals as those used to describe the signal transmission systems according to the first and sixth exemplary embodiments, and the description thereof is omitted.

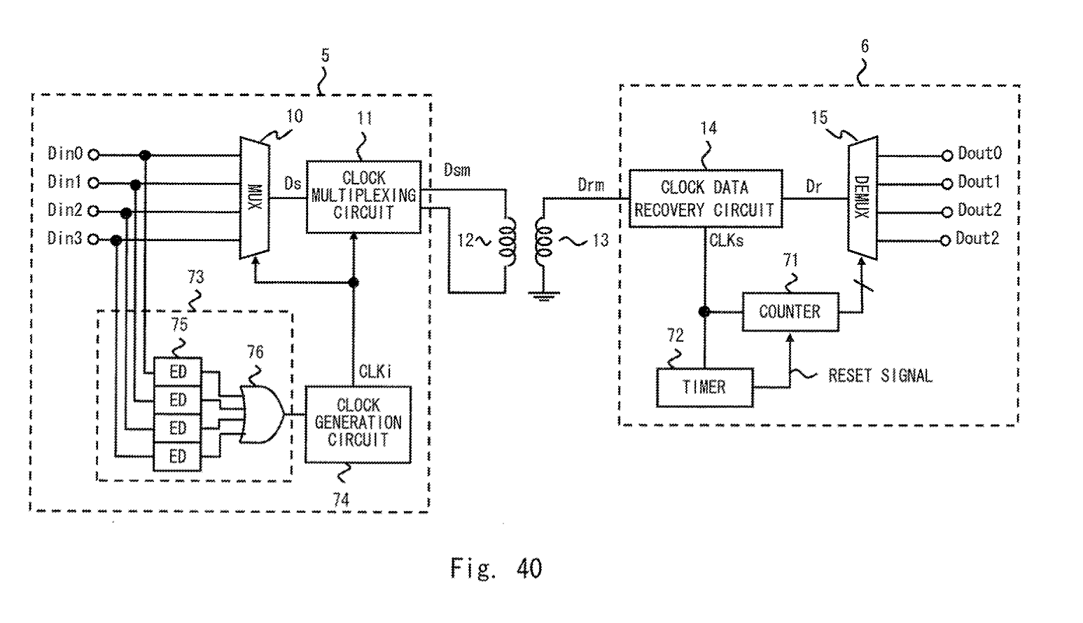

FIG. 40 shows a block diagram of the signal transmission system according to the seventh exemplary embodiment. As shown in FIG. 40, the signal transmission system according to the seventh exemplary embodiment has a configuration in which an edge detection circuit 73 and a clock generation circuit 74 are added to the signal transmission system according to the sixth exemplary embodiment. The edge detection circuit 73 includes a plurality of edge detect units ED corresponding to the number of items of first parallel data, and an OR circuit 76. Each of the edge detect units ED detects a rising edge or a falling edge of the corresponding data, and outputs an edge detection signal. The OR circuit 76 outputs a result of an OR operation between the edge detection signals, which are output by the plurality of edge detect units ED, to the clock generation circuit 74. Specifically, the edge detection circuit 73 detects a change generated in any of the plurality of data items, and notifies the detection result to a clock generation signal. The clock generation circuit generates the first clock signal CLKi during a period in which the edge detection circuit 73 detects the presence of an edge. That is, in the signal transmission system according to the seventh exemplary embodiment, the edge detection circuit 73 and the clock generation circuit 74 generate the first clock signal CLKi only during a period in which a change occurs in the data Din0 to Din3 (i.e., a period in which transmission data exists).

As described above, the signal transmission system according to the seventh exemplary embodiment determines whether or not to generate the first clock signal CLKi based on whether or not the period corresponds to a data transmission period. At this time, in the signal transmission system according to the seventh exemplary embodiment, the first clock signal CLKi can be generated according to the transmission data without controlling the first clock signal CLK1 together with the transmission data. This configuration prevents the first clock signal CLKi from being unnecessarily generated during a period in which no change occurs in the transmission data, and suppress the frequency of circuit operations. This makes it possible to reduce the power consumption of the signal transmission system according to the seventh exemplary embodiment.

### Eighth Exemplary Embodiment

A signal transmission system according to an eighth exemplary embodiment will be described. Hereinafter, the elements described in the signal transmission system according to the first exemplary embodiment are denoted by the same reference numerals as those used to describe the signal transmission system according to the first exemplary embodiment, and the description thereof is omitted.

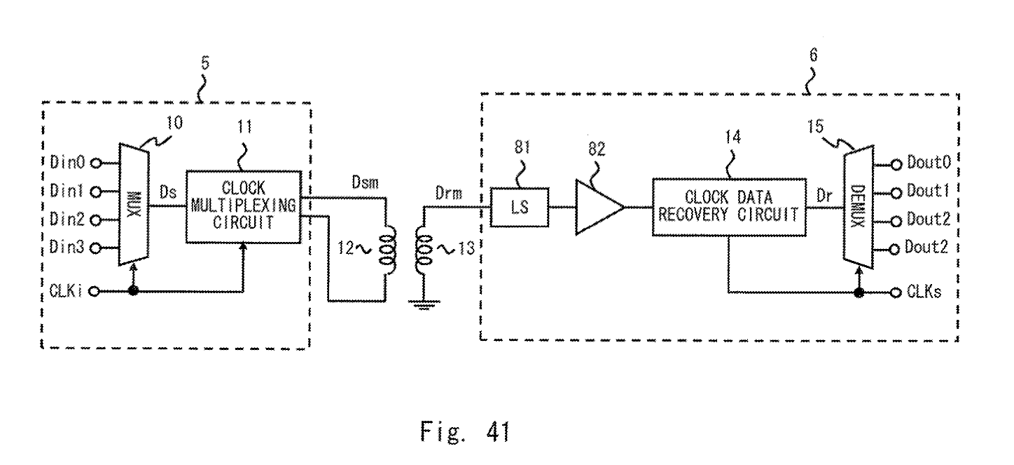

FIG. 41 shows a block diagram of the signal transmission system according to the eighth exemplary embodiment. As shown in FIG. 41, the signal'transmission system according to the eighth exemplary embodiment has a configuration in which a level shift circuit 81 and an amplifier 82 are added to the reception circuit 6 of the signal transmission system according to the first exemplary embodiment. The level shift circuit 81 adjusts the amplitude of the reception signal Drm, or adjusts an offset voltage. More specifically, the level shift circuit 81 adjusts the amplitude of the reception signal Drm to fall within an input dynamic range of the amplifier 82. Further, the level shift circuit 81 corrects the offset voltage of the reception signal Drm. The amplifier 82 amplifies the reception signal Drm, which is received through the level shift circuit 81, and transmits the reception signal Drm to the clock data recovery circuit 14 at the subsequent stage.

Thus, the provision of the level shift circuit 81 and the amplifier 82 enables application of the reception signal Drm having a stable amplitude and offset voltage to the clock data recovery circuit 14. This prevents the clock data recovery circuit 14 from making an error in extracting the second serial data Dr and the second clock signal CLKs. In sum, the signal transmission system according to the eighth exemplary embodiment can improve the reliability of the second serial data Dr and the second clock signal and improve the reliability of the second parallel data.

### Ninth Exemplary Embodiment

A signal transmission system according to a ninth exemplary embodiment will be described. Hereinafter, the elements described in the signal transmission systems according to the first and second exemplary embodiments are denoted by the same reference numerals as those used to describe the signal transmission systems according to the first and second exemplary embodiments, and the description thereof is omitted.

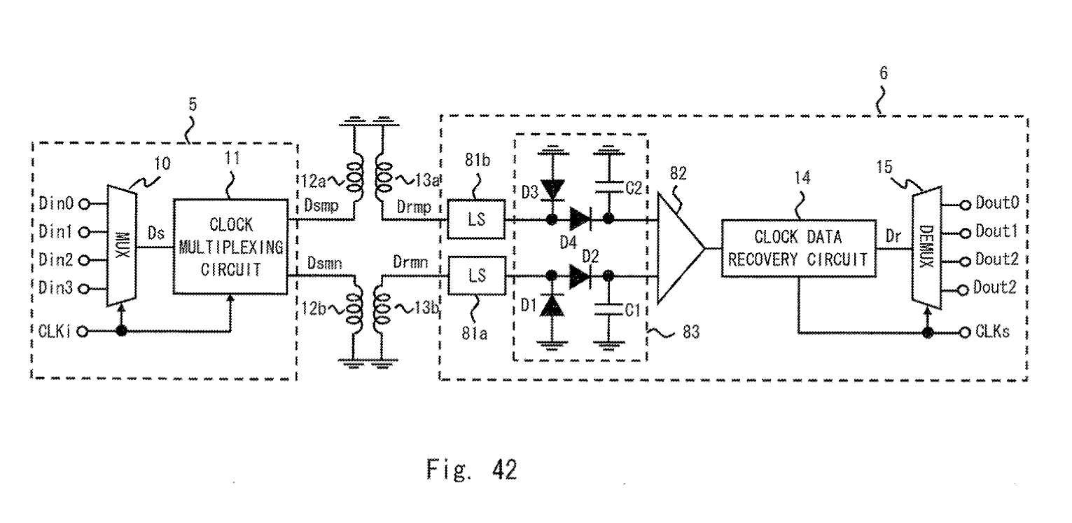

FIG. 42 shows a block diagram of the signal transmission system according to the ninth exemplary embodiment. As shown in FIG. 42, the signal transmission system according to the ninth exemplary embodiment has a configuration in which level shift circuits 81a and 81b, an amplifier 82, and a rectifier circuit 83 are added to the reception circuit 6 of the signal transmission system according to the second exemplary embodiment. The level shift circuit 81a adjusts the amplitude of the reception signal Drmn, or adjusts an offset voltage. The level shift circuit 81b adjusts the amplitude of the reception signal Drmp, or adjusts an offset voltage. More specifically, the level shift circuits 81a and 81b adjust the amplitudes of the reception signals Drmn and Drmp to fall within an input dynamic range of the amplifier 82. Further, the level shift circuits 81a and 81b correct the offset voltages of the reception signals Drmn and Drmp. The amplifier 82 is a differential amplifier which amplifies a voltage difference between the reception signals Drmn and Drmp, which are received through the level shift circuits 81 and the rectifier circuit 83, and transmits the voltage difference to the clock data recovery circuit 14 at the subsequent stage.

The rectifier circuit 83 is provided between the level shift circuits 81a and 81b and the amplifier 82. The rectifier circuit 83 includes diodes D1 to D4 and capacitors C1 and C2. The diode D1 has an anode connected to the ground terminal, and a cathode connected to an output node of the level shift circuit 81a. The diode D2 has an anode connected to the output node of the level shift circuit 81a, and a cathode connected to one input terminal of the differential amplifier. The capacitor C1 has one terminal connected to the ground terminal, and the other terminal connected to the one input terminal of the differential amplifier. The diode D3 has an anode connected to the ground terminal, and a cathode connected to an output node of the level shift circuit 81b. The diode D4 has an anode connected to the output node of the level shift circuit 81b, and a cathode connected to the other input terminal of the differential amplifier. The capacitor C2 has one terminal connected to the ground terminal, and the other terminal connected to the other input terminal of the differential amplifier.

The rectifier circuit 83 charges the capacitors C1 and C2 with a current flowing from the level shift circuits 81a and 81b toward the amplifier 82, and transmits a potential of a positive pulse signal to the amplifier 82. At the same time, the rectifier circuit 83 blocks a current flowing from the amplifier 82 to the level shift circuits 81a and 81b, thereby preventing transmission of a negative pulse signal to the amplifier 82. Further, the rectifier circuit prevents excessive rise of voltages output by the level shift circuits 81a and 81b due to the diodes D1 and D3.

Thus, the provision of the rectifier circuit 83 between the level shift circuits 81a and 81b and the amplifier 82 enables application of the reception signal Drm having a stable amplitude and offset voltage to the clock data recovery circuit 14. Particularly, when communication is carried out using two transformers, only the positive pulse signal is transmitted through the transformers. Accordingly, in such a case, the rectifier circuit 83 blocks a negative potential change of the reception signal Drm, which is accompanied by the positive pulse signal, thereby drastically improving the reliability of the second serial data. In sum, the signal transmission system according to the ninth exemplary embodiment can improve the reliability of the second serial data Dr and the second clock signal and also improve the reliability of the second parallel data.

Note that the present invention is not limited to the above exemplary embodiments, but can be modified without departing from the scope of the present invention.

This application is based upon and claims the benefit of priority from Japanese patent application No. 2009-027723, filed on Feb. 9, 2009, the disclosure of which is incorporated herein in its entirety by reference.

### INDUSTRIAL APPLICABILITY

The present invention is applicable to a system in which signals are transmitted and received between a circuit that operates in a first power supply system and a circuit that operates in a second power supply system to which a power supply voltage different from that of the first power supply system is set.

### REFERENCE SIGNS LIST

1 SEMICONDUCTOR PACKAGE
2 LEAD TERMINAL
3, 4, 7 SEMICONDUCTOR CHIP
5 TRANSMISSION CIRCUIT
6 RECEPTION CIRCUIT
8 SEMICONDUCTOR SUBSTRATE
10 MULTIPLEXER
11, 11a CLOCK MULTIPLEXING CIRCUIT
12, 12a, 12a PRIMARY COIL
13, 13a, 13b SECONDARY COIL
14, 14a CLOCK DATA RECOVERY CIRCUIT
15 DEMULTIPLEXER
16 WAVEFORM SHAPING CIRCUIT
17 ENCODING CIRCUIT
18 DECODING CIRCUIT
20 INVERTER
21, 23, 25 AND CIRCUIT
22, 24 PRE-BUFFER
26, 28 BUFFER CIRCUIT
27 AND CIRCUIT HAVING INVERTING INPUT
31 INVERTER
41, 42, 45, 46 PULSE DETECTOR
43, 48 HYSTERESIS COMPARATOR
44, 47 OR CIRCUIT
51 BUFFER CIRCUIT
52, 54 COMPARATOR
53 INVERTING BUFFER CIRCUIT
54 COMPARATOR
61 PEAK HOLD CIRCUIT
62 BUFFER CIRCUIT
63 BOTTOM HOLD CIRCUIT
64 INVERTING BUFFER CIRCUIT
65 DIFFERENTIAL AMPLIFIER
71 COUNTER
72 TIMER
73 EDGE DETECTION CIRCUIT
74 CLOCK GENERATION CIRCUIT
76 OR CIRCUIT
81, 81a, 81b LEVEL SHIFT CIRCUIT
82 AMPLIFIER
83 RECTIFIER CIRCUIT
BH1, BH2 BOTTOM HOLD SIGNAL
PH1, PH2 PEAK HOLD SIGNAL
C1, C2, Cc, Cd, Cu CAPACITOR
Ce1, Ce2 ELECTRODE
CLKi, CLKs CLOCK SIGNAL
D1-D4 DIODE
Dr SECOND SERIAL DATA
Drm, Drmn, Drmp RECEPTION SIGNAL
Drmf SHAPED RECEPTION SIGNAL
Ds FIRST SERIAL DATA
Dsm, Dsmn, Dsmp TRANSMISSION SIGNAL
ED EDGE DETECT UNIT
Ic DRIVE CURRENT
Is CURRENT SOURCE
N1-N9 NMOS TRANSISTOR
P1-N3 PMOS TRANSISTOR
Pd PAD
R1d, R1u RESISTOR
RL1, RL2 LOAD RESISTOR
Sd, Su DETECTION SIGNAL
VOUT NON-INVERTING OUTPUT TERMINAL
VOUTb INVERTING OUTPUT TERMINAL
Vref REFERENCE VOLTAGE
W BONDING WIRE

1. A signal transmission system comprising:
an AC coupling element that is connected between a transmitting node and a receiving node and couples the transmitting node and the receiving node in an alternating manner, the transmitting node and the receiving node being provided on semiconductor substrates electrically insulated from each other;
a first data conversion circuit that receives first parallel data and a first clock signal, and converts the first parallel data into first serial data according to the first clock signal;
a clock multiplexing circuit that multiplexes the first clock signal with the first serial data to generate a transmission signal, and outputs the transmission signal to the transmitting node;
a clock data recovery circuit that extracts second serial data corresponding to the first serial data and a second clock signal corresponding to the first clock signal from a reception signal received through the receiving node; and
a second data conversion circuit that converts the second serial data into second parallel data according to the second clock signal.

2. The signal transmission system according to claim 1, wherein
the first data conversion circuit includes a plurality of input terminals each receiving a single data item included in the first parallel data, and one output terminal, cyclically selects one of the plurality of input terminals in synchronization with the first clock signal, and outputs, to the output terminal, the single data item input to an input terminal selected, and
the second data conversion circuit includes one input terminal receiving the second serial data, and a plurality of output terminals each outputting a single data item included in the second parallel data, cyclically selects one of the plurality of output terminals in synchronization with the second clock signal, and outputs, to an output terminal selected, the second serial data input to the input terminal during the selection.

3. The signal transmission system according to claim 1, wherein
when the first serial data has a first logic level, the clock multiplexing circuit generates the transmission signal by superimposing a pulse signal fluctuating in a direction from the first logic level to a second logic level, on the first serial data in synchronization with the first clock signal, and
when the first serial data has a second logic level, the clock multiplexing circuit generates the transmission signal by superimposing a pulse signal fluctuating in a direction from the second logic level to the first logic level, on the first serial data in synchronization with the first clock signal.

4. The signal transmission system according to claim 1, wherein the clock data recovery circuit detects a potential change of the reception signal, changes a logic level of the second serial data, and generates the second clock signal.

5. The signal transmission system according to claim 1, wherein
when a pulse signal to be superimposed on the first serial data according to the first clock signal has a positive amplitude, the clock multiplexing circuit sets a time rate of change upon a rise of current output to the transmitting node to be greater than a time rate of change upon a fall of the current, and
when a pulse signal to be superimposed on the first serial data according to the first clock signal has a negative amplitude, the clock multiplexing circuit sets a time rate of change upon a rise of current output to the transmitting node to be smaller than a time rate of change upon a fall of the current.

6. The signal transmission system according to claim 1, wherein
the clock data recovery circuit includes:
a first pulse detection circuit that detects a positive potential change of the reception signal and outputs a first detection signal;
a second pulse detection circuit that outputs a negative potential change of the reception signal and outputs a second detection signal;
a hysteresis comparator that varies a potential of the second serial data according to a polarity of a potential difference between the first detection signal and the second detection signal; and
an OR circuit that varies a logic level of the second clock signal according to a result of an OR operation between the first detection signal and the second detection signal.

7. The signal transmission system according to claim 1, comprising a waveform shaping circuit provided between the clock data recovery circuit and the receiving node,
wherein the waveform shaping circuit includes:
a peak hold circuit that outputs a first hold voltage, a voltage value of the first hold voltage and a time period for holding the first hold voltage being determined according to a magnitude of a peak voltage of a positive potential change of the reception signal;
a peak hold circuit that outputs a second hold voltage, a voltage value of the second hold voltage and a time period for holding the second hold voltage being determined according to a magnitude of a peak voltage of a negative potential change of the reception signal;
an inverting amplifier that outputs a third hold voltage obtained by inverting a polarity of the second hold voltage; and
a differential amplifier that shapes a waveform of the reception signal according to a voltage difference between the first hold voltage and the third hold voltage, and outputs the reception signal shaped to the clock data recovery circuit.

8. The signal transmission system according to claim 1, comprising:
an encoding circuit that is provided on an input terminal side of the first data conversion circuit, and outputs, to the first data conversion circuit, parallel data obtained by appending header information corresponding to the first parallel data to the first parallel data; and
a decoding circuit that is provided on an output terminal side of the second data conversion circuit, identifies a first bit of the second parallel data based on the header information included in the second parallel data, and outputs data corresponding to the first parallel data out of the second parallel data.

9. The signal transmission system according to claim 1, comprising:
a timer that monitors the second clock signal, counts a stop time of the second clock signal, and outputs a reset signal when the stop time reaches a preset time; and
a counter that counts the number of clock edges of the second clock signal, outputs a count value, and resets the count value according to the reset signal,
wherein the second data conversion circuit switches an output terminal to output the second serial data according to the count value.

10. The signal transmission system according to claim 1, comprising:
an edge detection circuit that outputs a data change detection signal in response to a change of at least one data item included in the first parallel data; and
a clock generation circuit that receives the data change detection signal and generates the first clock signal.

11. The signal transmission system according to claim 1, comprising:
a level shift circuit that is connected to the receiving node, and shifts a signal level of the reception signal; and
an amplifier that amplifies the reception signal received through the level shift circuit, and outputs the reception signal amplified to the clock data recovery circuit.

12. The signal transmission system according to Claim
wherein the transmitting node includes a first transmitting node and a second transmitting node, and
the AC coupling element includes:
a first AC coupling element that couples the first transmitting node and a first receiving node in an alternating manner, the first transmitting node being compliant with transmission of data having a first logic level among data included in the first serial data, the first receiving node being provided so as to correspond to the first transmitting node; and
a second AC coupling element that couples a second transmitting node and a second receiving node in an alternating manner, the second transmitting node being compliant with transmission of data having a second logic level among data included in the first serial data, the second receiving node being provided so as to correspond to the second transmitting node.

13. The signal transmission system according to claim 12, wherein when the first serial data has the first logic level, the clock multiplexing circuit outputs a first transmission signal to the first AC coupling element, and when the first serial data has the second logic level, the clock multiplexing circuit outputs a second transmission signal to the second AC coupling element.

14. The signal transmission system according to claim 12, wherein the clock multiplexing circuit sets a time rate of change upon a rise of current output to the first AC coupling element and the second AC coupling element to be greater than a time rate of change upon a fall of the current.

15. The signal transmission system according claim 12,
wherein the clock data recovery circuit includes:
a hysteresis comparator that varies a potential of the second serial data according to a polarity of a voltage difference between a voltage generated at a terminal on the side of the first receiving node of the first AC coupling element and a voltage generated at a terminal on the side of the second receiving node of the second AC coupling element;
a first pulse detection circuit that detects a potential change generated at the terminal on the side of the first receiving node of the first AC coupling element, and outputs a first detection signal;
a second pulse detection circuit that detects a potential change generated at the terminal on the side of the second receiving node of the second AC coupling element, and outputs a second detection signal; and
an OR circuit that varies a logic level of the second clock signal according to a result of an OR operation between the first detection signal and the second detection signal.

16. The signal transmission system according to claim 12, comprising:
a first level shift circuit that is connected to a terminal on the side of the first receiving node of the first AC coupling element, and shifts a signal level of the reception signal;
a second level shift circuit that is connected to a terminal on the side of the second receiving node of the second AC coupling element, and shifts a signal level of the reception signal; and
an amplifier that amplifies the reception signal received through the first and second level shift circuits, and outputs the reception signal amplified to the clock data recovery circuit.

17. The signal transmission system according to claim 16, comprising a rectifier that is provided between the first and second level shift circuits and the amplifier, and rectifies the transmission signal transmitted to the amplifier from the first and second level shift circuits.

18. The signal transmission system according to claim 1, wherein the AC coupling element includes a primary coil connected to the transmitting node, and a secondary coil connected to the receiving node, the primary coil and the secondary coil being magnetically coupled together.

19. The signal transmission system according to claim 1, wherein the AC coupling element includes a capacitor having a first electrode connected to the transmitting node, a second electrode connected to the second receiving node, and a dielectric formed of an insulator filled between the first electrode and the second electrode.

20. A signal transmission method for transmitting and receiving a signal through an AC coupling element that is connected between a transmitting node and a receiving node and couples the transmitting node and the receiving node in an alternating manner, the transmitting node and the receiving node being provided on 1.5 semiconductor substrates electrically insulated from each other, the signal transmission method comprising:
converting first parallel data to be transmitted into first serial data according to a clock signal;
generating a transmission signal by multiplexing the clock signal with the first serial data; .
transmitting the transmission signal to the receiving node through the AC coupling element;
extracting second serial data corresponding to the first serial data and a second clock signal corresponding to a first clock signal from a reception signal received through the receiving node; and
converting the second serial data into second parallel data according to the second clock signal.

21. The signal transmission method according to claim 20, wherein the transmission signal is a signal obtained by superimposing a pulse signal on the first serial data in synchronization with the first clock signal, the pulse signal having an amplitude at a logic level opposite to a logic level of the first serial data.

22. The signal transmission method according to claim 20, wherein a logic level of the second serial data is determined according to a direction of a potential change of the reception signal, and a clock edge position of the second clock signal is determined according to a timing of the potential change of the reception signal.

23. The signal transmission method according to claim 20, wherein
when a pulse signal included in the transmission signal has a positive amplitude, a time rate of change upon a rise of current flowing to the transmitting node based on the transmission signal is greater than a time rate of change upon a fall of the current, and
when the pulse signal included in the transmission signal has a negative amplitude, a time rate of change upon a rise of the current is smaller than a time rate of change upon a fall of the current.

24. The signal transmission method according to claim 20, wherein
a potential level of the reception signal is held for a predetermined period according to a magnitude of a potential change of the reception signal,
a direction of the potential change of the reception signal is determined based on the potential level held, and
the second serial data is generated based on the determined direction of the potential change of the reception signal.

25. The signal transmission method according to claim 20, comprising:
generating header information corresponding to the first parallel data;
converting parallel data including the first parallel data and the header information into the first serial data;
identifying a first bit of the second parallel data based on the header information included in the second parallel data; and
outputting data corresponding to the first parallel data out of the second parallel data.

26. The signal transmission method according to claim 20, comprising:
counting the number of clock edges of the second clock signal and generating a count value;
measuring a stop time of the second clock signal;
resetting the count value representing the number of clock edges, when the stop time of the second clock signal reaches a preset time; and
converting the second serial data into the second conal parallel data according to the count value.

27. The signal transmission method according to claim 20, comprising:
detecting a change of at least one data item included in the first parallel data, and generating a data change detection signal; and
generating the first clock signal based on the data change detection signal.

28. The signal transmission method according to claim 20, comprising: shifting a signal level of the reception signal to generate the second serial data and the second clock signal based on a signal obtained by amplifying the reception signal after level shifting.

29. The signal transmission method according to claim 20, wherein the AC coupling element transmits, through different nodes, data of a first logic level and data of a second logic level among data included in the first serial data.
